(19) United States
(12) Patent Application Publication
(10) Pub. No.: US 2018/0097045 A1
(43) Pub. Date: Apr. 5, 2018

(54) DISPLAY DEVICE AND MANUFACTURING METHOD THEREOF

(71) Applicant: Japan Display Inc., Tokyo (JP)

(72) Inventor: Norihisa MAEDA, Tokyo (JP)

(21) Appl. No.: 15/718,463

(22) Filed: Sep. 28, 2017

(30) Foreign Application Priority Data
Oct. 5, 2016 (JP) 2016-197276

(51) Int. Cl. H01L 27/32; H01L 51/52; H01L 51/56

(52) U.S. Cl. CPC H01L 27/3232; H01L 27/3244; H01L 2227/323; H01L 51/5253; H01L 51/56; H01L 27/3211

(57) ABSTRACT

Provided is a display device including: a substrate; a first light-emitting element over the substrate; and a second light-emitting element located over the substrate and adjacent to the first light-emitting element. Each of the first light-emitting element and the second light-emitting element possesses: a first electrode; an EL layer over the first electrode; a second electrode over the EL layer; and a photochromic layer located over the second electrode and including a photochromic material. The photochromic material is different in chemical structure between the first light-emitting element and the second light-emitting element.

### CROSS REFERENCE TO RELATED APPLICATIONS

This application is based on and claims the benefit of priority from the prior Japanese Patent Application No. 2016-197276, filed on Oct. 5, 2016, the entire contents of which are incorporated herein by reference.

### FIELD

An embodiment of the present invention relates to a display device and a manufacturing method thereof. For example, an embodiment of the present invention relates to a display device having a plurality of display elements including a photochromic material and a manufacturing method thereof.

### BACKGROUND

An organic EL (Electroluminescence) display element is represented as an example of a display device. An organic EL display device has a plurality of pixels formed over a substrate, and each of the plurality of pixels includes an organic light-emitting element (hereinafter, referred to as a light-emitting element). A light-emitting element possesses a layer (hereinafter, referred to as an organic layer or an EL layer) including an organic compound between a pair of electrodes (cathode and anode) and is operated by supplying current between the pair of electrodes. Color provided by a light-emitting element is determined by a light-emitting material in an EL layer, and light emission with a variety of colors can be obtained by appropriately selecting a light-emitting material. Arrangement of a plurality of light-emitting elements giving different colors on a substrate makes it possible to reproduce a full-color image.

It has been known to provide a layer (hereinafter, referred to as a photochromic layer) including a photochromic material to a light-emitting element in order to improve reliability and performance of a light-emitting element. For example, Japanese Patent Application Publication No. 2014-72126 discloses a light-emitting element which is provided with a photochromic layer so that a substrate is sandwiched by an EL layer and a photochromic material. Visibility of the light-emitting element is improved by this structure. In Japanese Patent Application Publication No. 2016-149191, a light-emitting element is disclosed in which a photochromic layer is arranged between a cathode and a protection film (passivation film) formed over the cathode. In the light-emitting element with such a structure, deterioration (burning) of the light-emitting element can be suppressed due to the change in absorption property caused by isomerization of a photochromic material.

### SUMMARY

An embodiment of the present invention is a display device. The display device includes: a substrate; a first light-emitting element over the substrate; and a second light-emitting element located over the substrate and adjacent to the first light-emitting element. Each of the first light-emitting element and the second light-emitting element possesses: a first electrode; an EL layer over the first electrode; a second electrode over the EL layer; and a photochromic layer located over the second electrode and including a photochromic material. The photochromic material of the photochromic layer included in the first light-emitting element is different in chemical structure from the photochromic material of the photochromic layer included in the second light-emitting element.

An embodiment of the present invention is a display device. The display device includes: a substrate; a first light-emitting element over the substrate; and a second light-emitting element located over the substrate and adjacent to the first light-emitting element. Each of the first light-emitting element and the second light-emitting element possesses: a first electrode; an EL layer over the first electrode; a second electrode over the EL layer; a first photochromic layer located over the second electrode and including a first photochromic material; and a second photochromic layer located over the first photochromic layer and including a second photochromic material. The first photochromic material included in the first light-emitting element is different in chemical structure from the first photochromic material included in the second light-emitting element. The second photochromic material included in the first light-emitting element is different in chemical structure from the second photochromic material included in the second light-emitting element.

An embodiment of the present invention is a method for manufacturing a display device. The method includes: forming a first electrode in each of a first pixel and a second pixel adjacent to the first pixel; forming an EL layer over the first electrode of the first pixel and the first electrode of the second pixel; forming a second electrode over the EL layer; forming a photochromic layer including a photochromic material over the second electrode so that the photochromic layer is shared by the first pixel and the second pixel; and performing light irradiation on at least one of the first pixel and the second pixel to isomerize the photochromic material.

An embodiment of the present invention is a method for manufacturing a display device. The method includes: forming a first electrode in each of a first pixel and a second pixel adjacent to the first pixel; forming an EL layer over the first electrode of the first pixel and the first electrode of the second pixel; forming a second electrode over the EL layer; forming a first photochromic layer over the second electrode, the first photochromic layer extending from the first pixel to the second pixel and including a first photochromic material; forming a second photochromic layer including a second photochromic material over the first photochromic layer so as to be shared by the first pixel and the second pixel; performing light irradiation on one of the first pixel and the second pixel to isomerize one of the first photochromic material and the second photochromic material; and performing light irradiation on the other of the first pixel and the second pixel to isomerize the other of the first photochromic material and the second photochromic material.

### BRIEF DESCRIPTION OF DRAWINGS

FIG. 1 is a schematic cross-sectional view of a display device according to an embodiment of the present invention;

FIG. 2 is a schematic cross-sectional view of a display device according to an embodiment of the present invention;

FIG. 3 is a schematic cross-sectional view of a display device according to an embodiment of the present invention;

FIG. 4A to FIG. 4D are drawings for explaining an effect of a photochromic layer of a display device according to an embodiment of the present invention;

FIG. 5A to FIG. 5D are drawings for explaining an effect of a photochromic layer of a display device according to an embodiment of the present invention;

FIG. 6A to FIG. 6D are drawings for explaining an effect of a photochromic layer of a display device according to an embodiment of the present invention;

FIG. 7A and FIG. 7B are schematic cross-sectional views of a display device according to an embodiment of the present invention;

FIG. 8A and FIG. 8B are schematic cross-sectional views of a display device according to an embodiment of the present invention;

FIG. 9 is a schematic cross-sectional view of a display device according to an embodiment of the present invention;

FIG. 10A to FIG. 10D are drawings for explaining an effect of a photochromic layer of a display device according to an embodiment of the present invention;

FIG. 11 is a schematic perspective view of a display device according to an embodiment of the present invention;

FIG. 12 is a schematic cross-sectional view of a display device according to an embodiment of the present invention;

FIG. 13A to FIG. 13C are schematic cross-sectional views for explaining a manufacturing method of a display device according to an embodiment of the present invention;

FIG. 14A to FIG. 14C are schematic cross-sectional views for explaining a manufacturing method of a display device according to an embodiment of the present invention;

FIG. 15A and FIG. 15B are schematic cross-sectional views for explaining a manufacturing method of a display device according to an embodiment of the present invention;

FIG. 16A and FIG. 16B are schematic cross-sectional views for explaining a manufacturing method of a display device according to an embodiment of the present invention;

FIG. 17A and FIG. 17B are schematic cross-sectional views for explaining a manufacturing method of a display device according to an embodiment of the present invention;

FIG. 18A and FIG. 18B are schematic cross-sectional views for explaining a manufacturing method of a display device according to an embodiment of the present invention;

FIG. 19A and FIG. 19B are schematic cross-sectional views for explaining a manufacturing method of a display device according to an embodiment of the present invention; and

FIG. 20 is a schematic cross-sectional view for explaining a manufacturing method of a display device according to an embodiment of the present invention;

### DESCRIPTION OF EMBODIMENTS

Hereinafter, the embodiments of the present invention are explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

In the present invention, when a plurality of films is formed by performing etching or light irradiation on one film, the plurality of films may have functions or rules different from each other. However, the plurality of films originates from a film formed as the same layer in the same process and has the same layer structure and the same material. Therefore, the plurality of films is defined as films existing in the same layer.

In the specification and the scope of the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

### First Embodiment

### 1. Structure

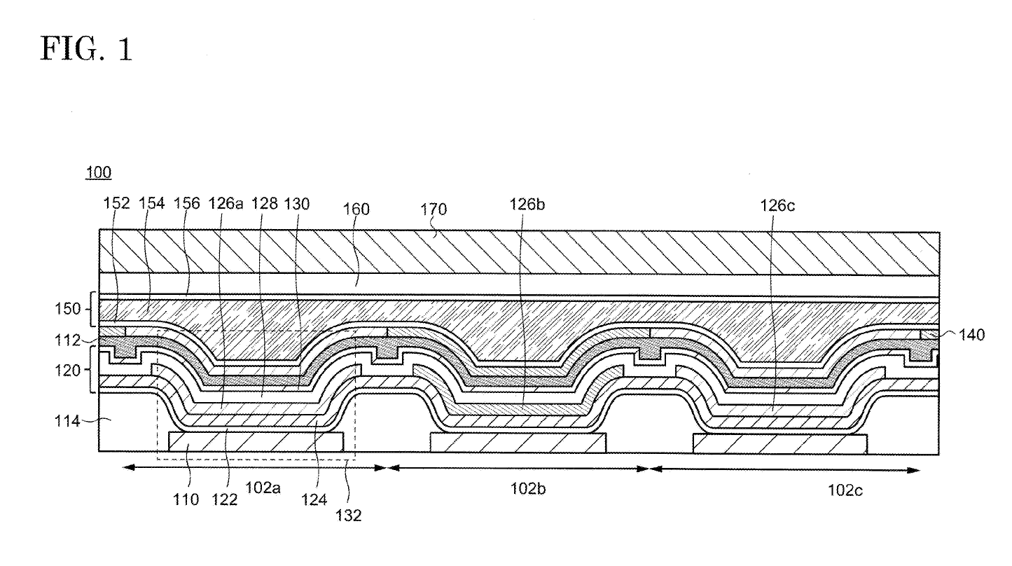

FIG. 1 is a schematic cross-sectional view of a display device 100 according to the First Embodiment of the present invention. The display device 100 possesses a plurality of pixels 102, and three pixels 102a, 102b, and 102c of the plurality of pixels 102 are illustrated in this cross-sectional view. The pixel 102b is adjacent to the pixel 102a and the pixel 102c. Note that a substrate for supporting the pixels 102 and a variety of circuits for driving the pixels 102 are omitted in FIG. 1.

The pixels 102a, 102b, and 102c each have a first electrode 110 and a second electrode 112. The first electrodes 110 are independently disposed in the pixels 102a, 102b, and 102c and electrically disconnected from one another by a partition wall 114. The partition wall 114 covers edge portions of the first electrodes 110 and has a role to absorb depressions and projections caused by a thickness of the first electrode 110. The second electrode 112 is continuously provided over the plurality of pixels 102a, 102b, and 102c. Thus, the second electrode 112 is shared by the plurality of pixels 102a, 102b, and 102c. One of the first electrode 110 and the second electrode 112 functions as an anode, while the other functions as a cathode. Light emission from the pixels 102a, 102b, and 102c is extracted through one or both of the first electrode 110 and the second electrode 112. The following explanation is provided by using an example in which the first electrode 110 and the second electrode 112 respectively function as an anode and a cathode, the first electrode 110 reflects light, and light emission from the pixels 102a, 102b, and 102c is extracted through the second electrode 112. However, an embodiment of the present invention is not limited to such a structure. For instance, the first electrode 110 may be used as a cathode.

An EL layer 120 is provided between the first electrode 110 and the second electrode 112 in each of the pixels 102a, 102b, and 102c. A structure of the EL layer 120 is arbitrarily determined, and the EL layer 120 may be configured with a plurality of layers having different functions. In the display device 100 shown in FIG. 1, the pixels 102a, 102b, and 102c each have a hole-injection layer 122, a hole-transporting layer 124, an emission layer 126, an electron-transporting layer 128, and an electron-injection layer 130. Each layer may have a single-layer structure or may be formed with a stack of different materials. Alternatively, it is not necessary that the EL layer 120 have all of these layers and may further include a layer having another function. For example, the EL layer 120 may include a hole-blocking layer, an electron-blocking layer, an exciton-blocking layer, or the like. A light-emitting element 132 is formed by the first electrode 110, the second electrode 112, and the EL layer 120 in each of the pixels 102a, 102b, and 102c.

A potential difference is provided between the first electrode 110 and the second electrode 112, by which holes and electrodes are injected to the EL layer 120 from the former and latter, respectively. Holes are transported to the emission layer 126 through the hole-injection layer 122 and the hole-transporting layer 124. Electrons are transported to the emission layer 126 through the electron-injection layer 130 and the electron-transporting layer 128. Holes and electrons are recombined in the emission layer 126, giving an excited state of a light-emitting material included in the emission layer 126. When the excited state is relaxed to a ground state, light with a wavelength corresponding to an energy difference between the excited state and the ground state is released and observed as light emission from the light-emitting element 132.

In the structure of FIG. 1, the EL layer 120 other than the emission layer 126, that is, the hole-injection layer 122, the hole-transporting layer 124, the electron-transporting layer 128, and the electron-injection layer 130 are continuously formed in the pixels 102a, 102b, and 102c and shared by the pixels 102a, 102b, and 102c. On the other hand, the emission layer 126 is independently formed in each of the pixels 102a, 102b, and 102c. The use of such a structure allows the pixels 102a, 102b, and 102c to respectively have emission layers (126a, 126b, and 126c) including light-emitting materials different from one another, by which emission colors different from one another can be obtained. For example, when the emission layers 126a, 126b, and 126c include light-emitting materials respectively giving blue, green, and red emission, full-color display can be achieved by extracting three primary colors from the pixels 102a, 102b, and 102c. In the example shown in FIG. 1, the emission layers 126a, 126b, and 126c are not in contact with one another, and the hole-transporting layer 124 and the electron-transporting layer 128 are in contact with each other over the partition wall 114. However, the emission layers 126a, 126b, and 126c may be formed so as to overlap with one another over the partition wall 114.

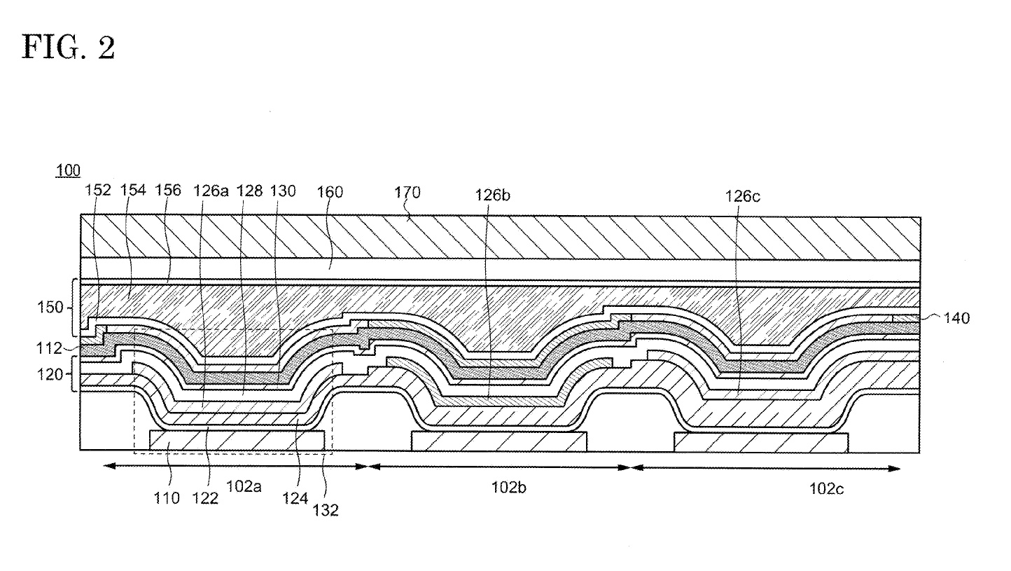

In the display device 100 shown in FIG. 1, the layers other than the emission layer 126 have the same structure between the pixels 102a, 102b, and 102c. However, these layers may have different structures or thicknesses between the pixels. For example, as shown in FIG. 2, the display device 100 may be configured so that a thickness of the hole-transporting layer 124 is different between the pixels 102a, 102b, and 102c. Alternatively, although not shown, thicknesses or a stacking structure of the hole-injection layer 122 and the electron-transporting layer 128 may be different between the pixels. Such a configuration of the display device 100 makes it possible to change a distance between the emission layer 126 attributed to an emission region and the first electrode 110 or a distance between the emission layer 126 and the second electrode 112 between the pixels. With this configuration, an optical distance between the first electrode 110 and the second electrode 112 can be changed in each pixel 102. As a result, the effects of light interference between the first electrode 110 and the second electrode 112 can be controlled, by which emission intensity and emission color can be controlled.

The display device 100 possesses a photochromic layer 140 over the second electrode 112. The photochromic layer 140 may be in contact with the second electrode 112. The photochromic layer 140 may be continuously formed over the pixels 102a, 102b, and 102c. In this case, the photochromic layer 140 is shared by the pixels 102a, 102b, and 102c. The photochromic layer 140 may include a photochromic material. A photochromic material is a compound exhibiting photochromism and reversibly shows color change (i.e., absorption property) upon light irradiation. More specifically, a photochromic material is a compound which varies in chemical structure by absorbing light with a specific wavelength to undergo isomerization, which accompanies change in a light-absorption property, that is, a light-absorption spectrum, due to a change of a conjugation system in the compound. After isomerization, a photochromic material is capable of retrieving an original structure by absorbing light with a different wavelength or thermal energy. Generally, a photochromic material is able to exist in two thermodynamically stable states (structures). These two states are in a reversible equilibrium state, and a photochromic material transits therebetween by absorbing light or thermal energy as described above.

The photochromic layer 140 may contain the same photochromic material in the pixels 102a, 102b, and 102c. However, in a part of the pixels, the photochromic material can exist in a structure different from that in other pixels. That is, two stable states which are taken by the photochromic material can be separately selected pixel-by-pixel. In the cases shown in FIG. 1 and FIG. 2, for example, the chemical structure of the photochromic material in the photochromic layer 140 is the same in the pixels 102a and 102c but is different in the pixel 102b. In this case, although the composition of the photochromic material is the same between all of the pixels 102a, 102b, and 102c, the absorption property of the photochromic material in the pixels 102a and 102c is different from that in the pixel 102b. Alternatively, the photochromic material may have the same chemical structure between all of the pixels 126a, 126b, and 126c.

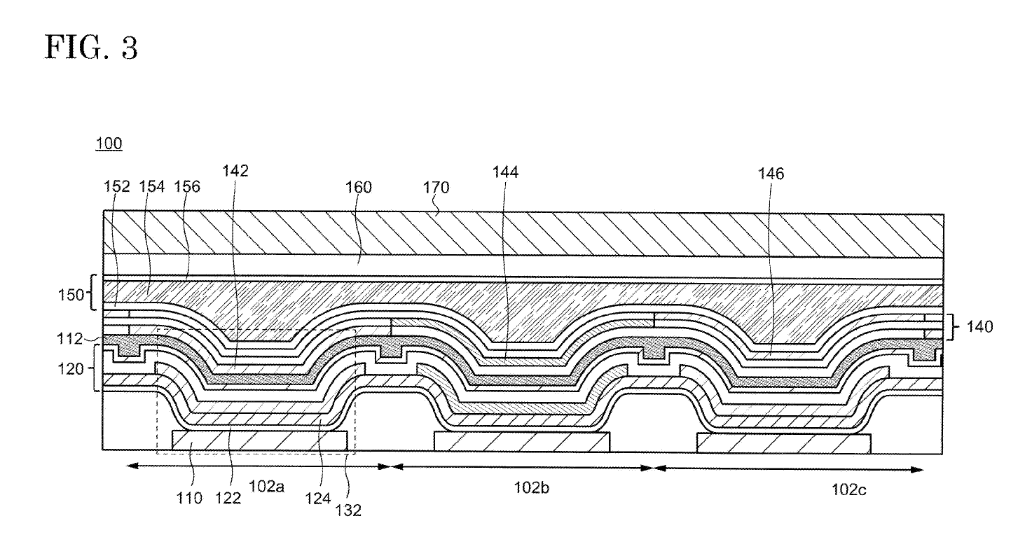

The number of photochromic layers of the display device 100 is arbitrarily determined. For example, the photochromic layer 140 may have a stacked structure including a plurality of layers as shown in FIG. 3. A structure is shown in FIG. 3 in which three photochromic layers (a first photochromic layer 142, a second photochromic layer 144, and a third photochromic layer 146) are arranged. In this case, although the photochromic material is the same regardless of the pixels in each of the first photochromic layer 142, the second photochromic layer 144, and the third photochromic layer 146, the first photochromic layer 142, the second photochromic layer 144, and the third photochromic layer 146 may contain different photochromic materials from one another.

When the photochromic layer 140 has a stacked structure, it is possible to arbitrarily select, pixel-by-pixel, the chemical structure of the photochromic material of each of the photochromic layers 142, 144, and 146. In the example shown in FIG. 3, the composition of the photochromic material is the same between the pixels 102a, 102b, and 102c in the first photochromic layer 142. However, the structure of the photochromic material in the pixel 102a is different from those in the pixels 102b and 102c. The composition of the photochromic material is the same between the pixels 102a, 102b, and 102c in the second photochromic layer 144. However, the structure of the photochromic material in the pixel 102b is different from those in the pixels 102a and 102c. The composition of the photochromic material is the same between the pixels 102a, 102b, and 102c in the third photochromic layer 144. However, the structure of the photochromic material in the pixel 102c is different from those in the pixels 102a and 102b. Such a design of the photochromic layer 140 allows the absorption properties of the photochromic layer 140 in the pixels 102a, 102b, and 102c to be different from one another. This feature will be described later.

Although not shown, the photochromic layer 140 may have a single-layer structure and include a plurality of different photochromic materials. In this case, the photochromic materials are selected so that their absorption properties are different from one another.

The display device 100 may have a passivation film 150 over the photochromic layer 140 (see FIG. 1 to FIG. 3). The passivation film 150 covers the EL layer 120 and has a function to prevent impurities such as water and oxygen from entering the light-emitting element 132 from outside, thereby improving reliability of the light-emitting element 132.

The structure of the passivation film 150 can be arbitrarily determined, and the passivation film 150 may have a three-layer structure as shown in FIG. 1 to FIG. 3, for example. In this case, the passivation film 150 may have a first layer 152, a second layer 154, and a third layer 156. The first layer 152 and the third layer 156 may be formed with an inorganic compound including silicon nitride and silicon oxide, and the second layer 154 may be formed with an organic compound including an acrylic resin, for example. The second layer 154 may be formed at a thickness so that depressions and projections caused by the partition wall 114 and the like are absorbed and a flat surface is provided.

A substrate 170 may be arranged over the passivation film 150 through a filler 160. The filler also serves as an adhesive. When a substrate is additionally provided under the first electrode 110, the substrate 170 is called an opposing substrate. The display device 100 including the light-emitting element 132 is physically protected by the substrate 170.

### 2. Optical Property of Photochromic Layer

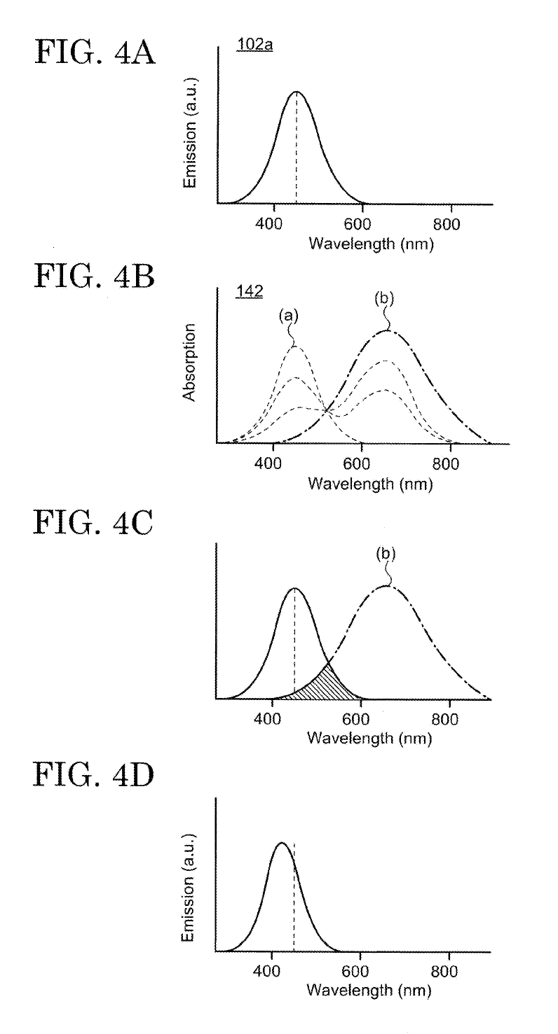

An example for controlling performance of the display device 100 shown in FIG. 3 with the photochromic layer 140 is explained by using FIG. 4A to FIG. 6D. Here, explanation is provided for a case where the photochromic layer 140 of the display device 100 has the first photochromic layer 142, the second photochromic layer 144, and the third photochromic layer 146, and the emission layers 126a, 126b, and 126c respectively giving blue, green, and red emissions are respectively formed in the pixels 102a, 102b, and 102c. Note that the stacking order of the first photochromic layer 142, the second photochromic layer 144, and the third photochromic layer 146 is not limited to that shown in FIG. 3, and the first photochromic layer 142, the second photochromic layer 144, and the third photochromic layer 146 may be stacked in an arbitrary order.

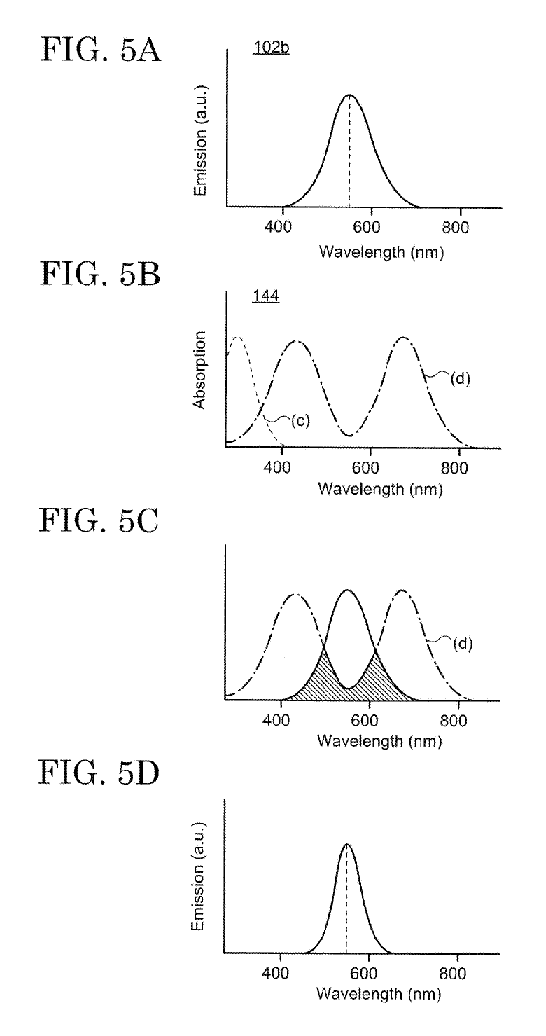

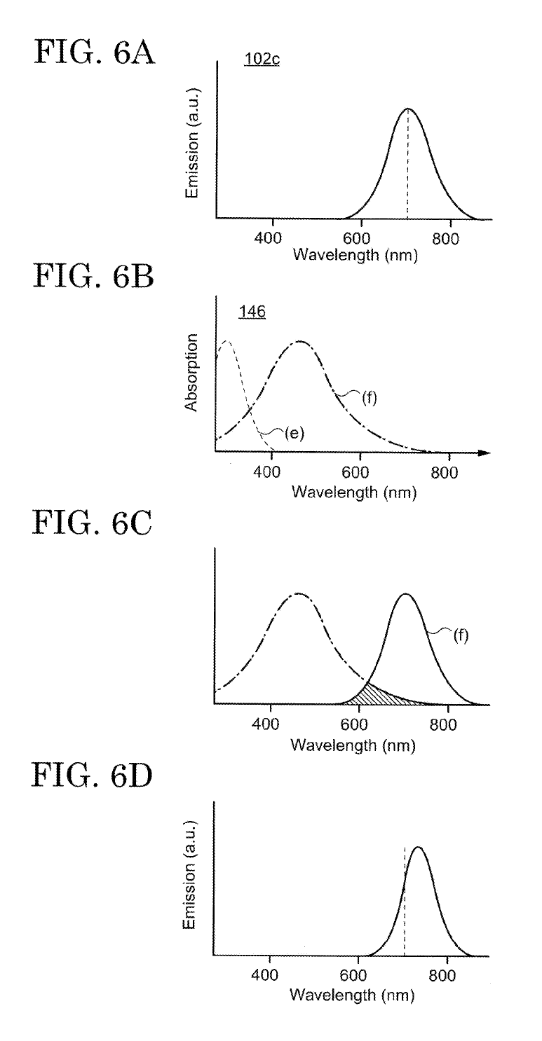

Emission properties of the light-emitting elements 132 disposed in the pixels 102a, 102b, and 102c are shown in FIG. 4A, FIG. 5A, and FIG. 6A, respectively. As illustrated in these figures, light having a peak in a blue region (e.g., around 450 nm), light having a peak in a green region (e.g., around 550 nm), and light having a peak in a red region (e.g., around 700 nm) are respectively obtained from the emission layers 126a, 126b, and 126c of the light-emitting elements 132 arranged in the pixels 102a, 102b, and 102c, respectively.

FIG. 4B, FIG. 5B, and FIG. 6B are respectively schematic drawings of variation of absorption spectra of the photochromic materials included in the first photochromic layer 142, the second photochromic layer 144, and the third photochromic layer 146. As shown in FIG. 4B, before light irradiation, the first photochromic layer 142 does not have an absorption or show an absorption peak in a green to red region (e.g., from 550 nm to 700 nm), but possesses an absorption (absorption (a)) in an ultraviolet region (e.g., around 350 nm), for example. Isomerization proceeds upon applying light with a wavelength in this region, and the absorption spectrum is gradually changed. That is, the absorption observed before light irradiation is gradually decreased, a new absorption appears in a green to red region, and its intensity is gradually increased (absorption (b)).

As shown in FIG. 5B, before light irradiation, the second photochromic layer 144 does not have an absorption or show an absorption peak in a green region, but possesses an absorption (absorption (c)) in an ultraviolet region, for example. Isomerization proceeds upon irradiation of light with this absorption wavelength, and the absorption spectrum is gradually changed. That is, the absorption observed before light irradiation is gradually decreased, a new absorption appears in blue and red regions, and its intensity is gradually increased (absorption (d)).

As shown in FIG. 6B, before light irradiation, the third photochromic layer 146 does not have an absorption or show an absorption peak in a red region, but possesses an absorption (absorption (e)) in an ultraviolet region, for example. Isomerization proceeds upon irradiation of light with this absorption wavelength, and the absorption spectrum is gradually changed. That is, the absorption observed before light irradiation is gradually decreased, a new absorption appears in blue and green regions (e.g., 400 nm to 600 nm), and its intensity is gradually increased (absorption (f)).

FIG. 4C shows a schematic drawing in which the absorption (b) and the emission spectrum (FIG. 4A) provided by the emission layer 126a in the pixel 102a are overlapped. As shown in FIG. 4C, a part of the emission overlaps with the absorption (b) (shaded portion). Therefore, a part of the emission from the emission layer 126a is absorbed by the isomerized photochromic material. In this case, the emission on a long-wavelength side is absorbed from the emission of the emission layer 126a. As a result, the emission spectrum on a long-wavelength side is removed from the entire emission spectrum, which simultaneously causes a shift of the emission peak of the pixel 102a to a short-wavelength side and reduction of a width of the emission spectrum as shown in FIG. 4D. Hence, the pixel 102a is capable of providing blue emission with excellent color purity.

As described above, the use of a photochromic material which does not have an absorption or show an absorption peak in a green to red region before isomerization and which does not provide an absorption or show an absorption peak in a blue region but provides an absorption in a green to red region after isomerization in the first photochromic layer 142 and the selective photo-isomerization of this photochromic material in the pixel 102a giving blue emission makes it possible to remove emission on a long-wavelength side from the emission of the pixel 102a. Accordingly, color purity of the blue-emissive pixel 102a can be improved. In this case, since light-irradiation is not carried out on the first photochromic layer 142 in the green-emissive pixel 102b and the red-emissive pixel 102c, the emissions from the pixels 102b and 102c are able to pass through the first photochromic layer 142. Hence, even if the first photochromic layer 142 is formed over the pixels 102b and 102c, the emission therefrom is not greatly influenced, and reduction in emission efficiency can be prevented.

Similarly, FIG. 5C shows a schematic drawing in which the absorption (d) and the emission spectrum (FIG. 5A) provided by the emission layer 126b of the pixel 102b are overlapped. As shown in FIG. 5C, a part of the emission overlaps with the absorption (d) (shaded portion). Therefore, a part of the emission from the emission layer 126b is absorbed by the isomerized photochromic material. In this case, the emission on a long-wavelength side and that on a short-wavelength side are absorbed from the emission of the emission layer 126b. As a result, as shown in FIG. 5D, the emission spectrum on a long-wavelength side and that on a short-wavelength side are removed from the entire emission spectrum, which causes a reduction of a width of the emission spectrum from the pixel 102b. Hence, green emission with excellent color purity can be provided.

As described above, the use of a photochromic material which does not have an absorption or show an absorption peak in blue and red regions before isomerization and which does not provide an absorption or show an absorption peak in a green region but provides an absorption in blue and red regions after isomerization in the second photochromic layer 144 and the selective photo-isomerization of this photochromic material in the pixel 102b giving green emission makes it possible to remove emission on a long-wavelength side and emission on a short-wavelength side from the emission of the pixel 102b. Accordingly, color purity of the green-emissive pixel 102b can be improved. In this case, since light-irradiation is not carried out on the second photochromic layer 144 in the blue-emissive pixel 102a and the red-emissive pixel 102c, the emissions from the pixels 102a and 102c are able to pass through the second photochromic layer 144. Hence, even if the second photochromic layer 144 is formed over the pixels 102a and 102c, the emission therefrom is not greatly influenced, and reduction in emission efficiency can be prevented.

Similarly, FIG. 6C shows a schematic drawing in which the absorption (f) and the emission spectrum (FIG. 6A) provided by the emission layer 126c of the pixel 102c are overlapped. As shown in FIG. 6C, a part of the emission overlaps with the absorption (f) (shaded portion). Therefore, a part of the emission from the emission layer 126c is absorbed by the isomerized photochromic material. In this case, the emission on a short-wavelength side is absorbed from the emission of the emission layer 126c. As a result, as shown in FIG. 6D, the emission spectrum on a long-wavelength side is removed from the entire emission spectrum, which simultaneously causes a shift of the emission peak of the pixel 102c to a long-wavelength side and a reduction of a width of the emission spectrum. Hence, red emission with excellent color purity can be provided.

As described above, the use of a photochromic material which does not have an absorption or show an absorption peak in a blue to green region before isomerization and which does not provide an absorption or show an absorption peak in a red region but provides an absorption in a blue to green region after isomerization in the third photochromic layer 146 and the selective photo-isomerization of this photochromic material in the pixel 102c giving red emission makes it possible to remove emission on a short-wavelength side from the emission of the pixel 102c. Accordingly, color purity of the red-emissive pixel 102c can be improved. In this case, since light-irradiation is not carried out on the third chromic layer 146 in the blue emissive pixel 102a and the green-emissive pixel 102b, the emissions from the pixels 102a and 102b are able to pass through the third photochromic layer 146. Hence, even if the third photochromic layer 146 is formed over the pixels 102a and 102b, the emission therefrom is not greatly influenced, and reduction in emission efficiency can be prevented.

The structure of the photochromic layer 140 is not limited to the combination exhibiting the aforementioned characteristics. The photochromic layer 140 may be a layer in which a photochromic material included therein does not have an absorption or show an absorption peak in a part of a visible region but possesses an absorption or an absorption peak in other regions after photo-isomerization. For example, the photochromic material may be a material which does not have an absorption or show an absorption peak in one or two of red, blue, and green regions but possesses an absorption or an absorption peak in other regions after photo-isomerization. Additionally, it is preferred that the photochromic material do not have an absorption or show an absorption peak in other regions before photo-isomerization. When the photochromic layer 140 is structured with a plurality of layers, it is preferred that the photochromic materials included in each of the layers be different in absorption wavelength from one another.

The use of the photochromic layer 140 having such optical properties enables it to improve color purity of the emission from the pixels 102 and realize high color reproducibility. Additionally, a part of external light is absorbed by the photochromic layer 140 by which reflection of external light can be suppressed in the display device 100. Accordingly, visibility of an image reproduced on the display device 100 is improved, and a high-quality image with high contrast can be provided.

### Second Embodiment

In the present embodiment, display devices 180, 182, 184, and 186 different in structure from the display device 100 described in the First Embodiment are explained. Explanation of the structures the same as those of the First Embodiment may be omitted.

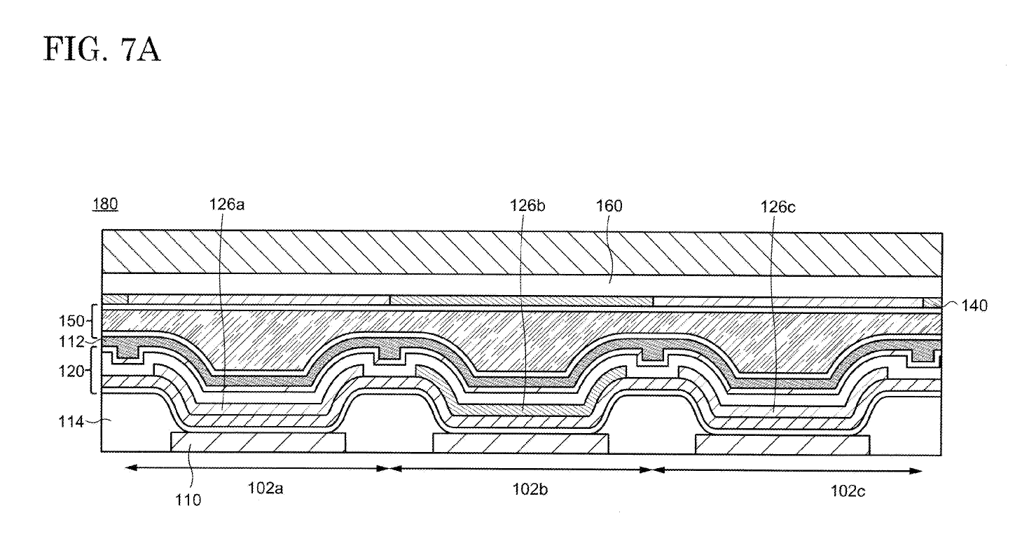

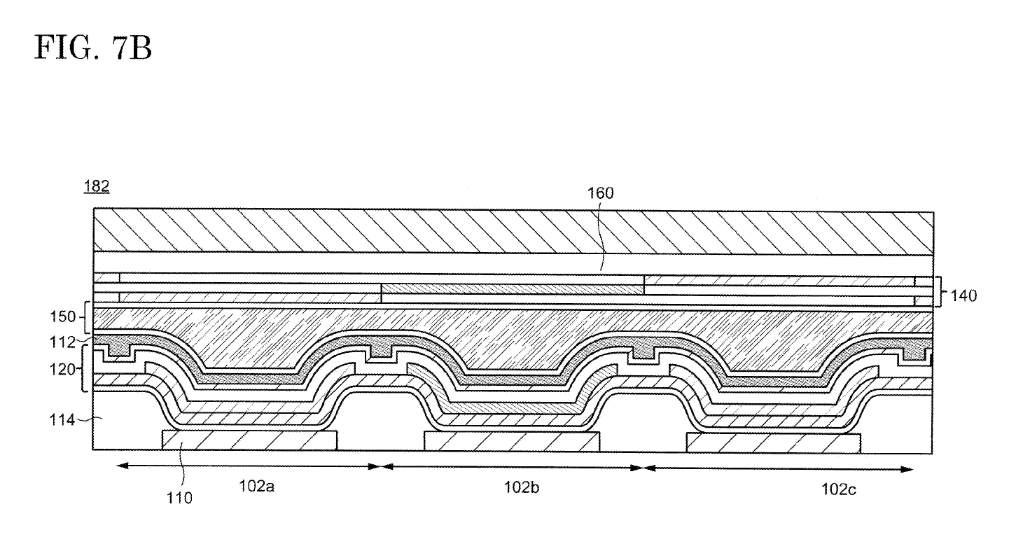

FIG. 7A shows a schematic cross-sectional view of the display device 180. The display device 180 is different from the display device 100 in that the photochromic layer 140 is formed over the passivation film 150. Therefore, the photochromic layer 140 is located between the passivation film 150 and the filler 160.

In the display device 182 shown in FIG. 7B, the photochromic layer 140 has a three-layer structure, and the display device 182 is different from the display device 180 in that the first photochromic layer 142, the second photochromic layer 144, and the third photochromic layer 146 are included. In this case, the photochromic layer 140 is also located between the passivation film 150 and the filler 160.

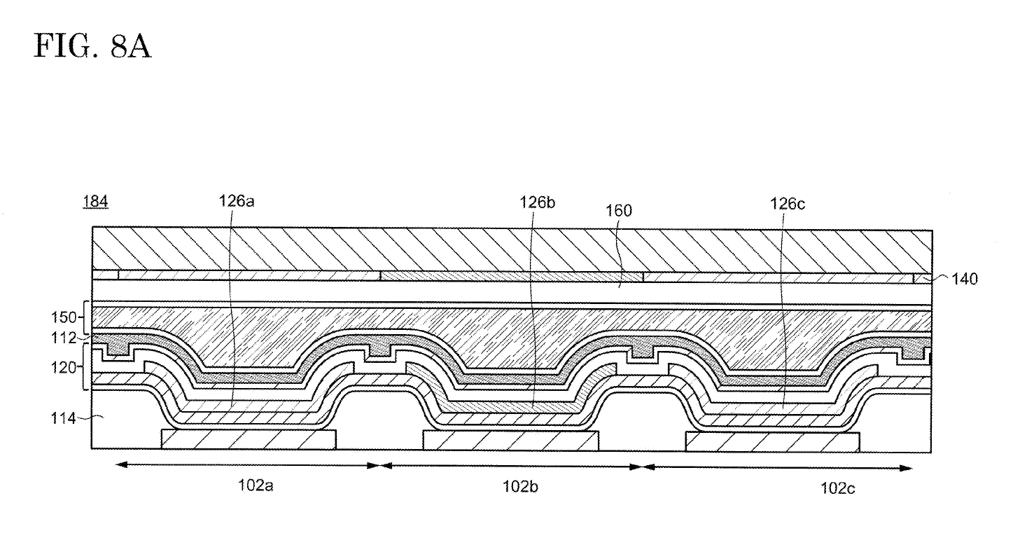

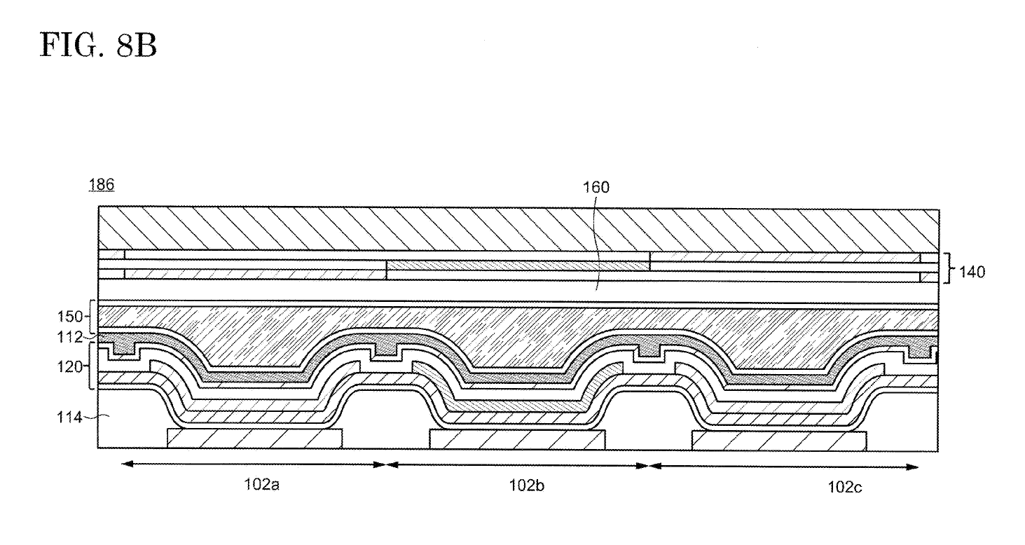

FIG. 8A shows a schematic cross-sectional view of the display device 184. The display device 184 is different from the display device 180 in that the photochromic layer 140 is formed over the filler 160. Therefore, the photochromic layer 140 is located between the filler 160 and the substrate 170.

In the display device 186 shown in FIG. 8B, the photochromic layer 140 has a three-layer structure, and the display device 186 is different from the display device 184 in that the first photochromic layer 142, the second photochromic layer 144, and the third photochromic layer 146 are included. In this case, the photochromic layer 140 is also located between the filler 160 and the substrate 170.

In these structures, no adverse influence is exerted on the light-emitting elements 132 even if the light-emitting elements 132 are formed by applying a wet-type film-forming method such as an ink-jet method, a printing method, or a spin-coating method because the light-emitting elements 132 are protected by the passivation film 150. Thus, a display device with high reliability can be produced at low cost.

### Third Embodiment

In the present embodiment, display device 190 having a different structure from the display devices 100, 180, 182, 184, and 186 described in the First and Second Embodiments is explained. Explanation of the structures the same as those of the First and Second Embodiments may be omitted.

### 1. Structure

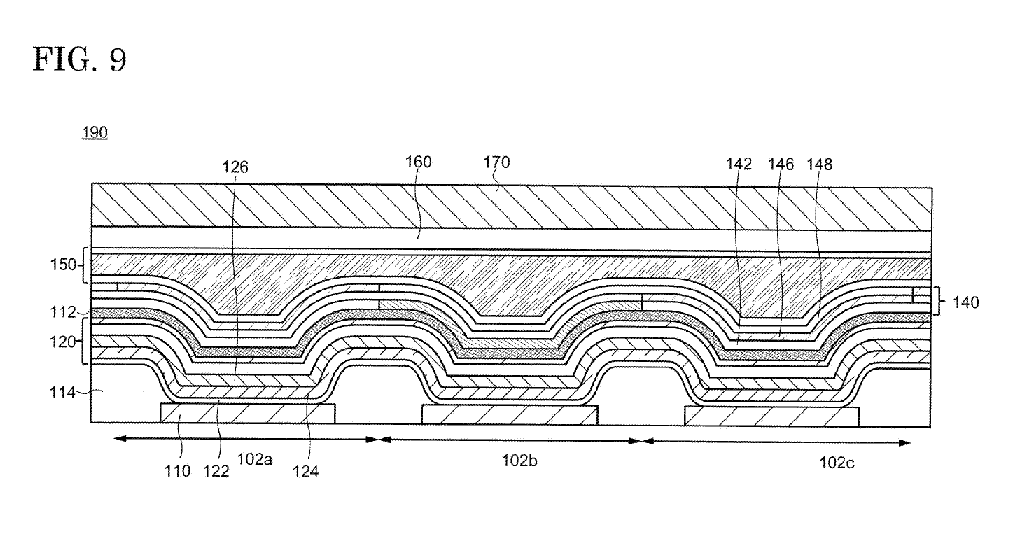

The display device 190 is different from the display devices 100, 180, 182, 184, and 186 in that the emission layer 126 of the EL layer 120 included in the plurality of pixels 102 is the same and that the EL layer 120 is configured to give white emission. More specifically, the emission layer 126 has the same structure between the pixels 102a, 102b, and 102c as shown in FIG. 9. In this case, the emission layer 126 can be continuously prepared over the pixels 102a, 102b, and 102c and shared by the pixels 102a, 102b, and 102c. The emission layer 126 may have a structure in which three emission layers respectively providing blue, green, and red colors are stacked, for example. Alternatively, the emission layer 126 may have a structure in which emission layers respectively providing blue and yellow colors are stacked. Alternatively, the emission layer 126 may have a structure in which emission layers respectively providing blue-green and red colors are stacked. Note that the layers other than the emission layer 126 may have different structures between the adjacent pixels 102.

The photochromic layer 140 may be structured with a single layer similar to the display device 100 or include a plurality of photochromic layers (e.g., the first photochromic layer 142, the second photochromic layer 144, and the third photochromic layer 146) as shown in FIG. 9.

### 2. Optical Property of Photochromic Layer

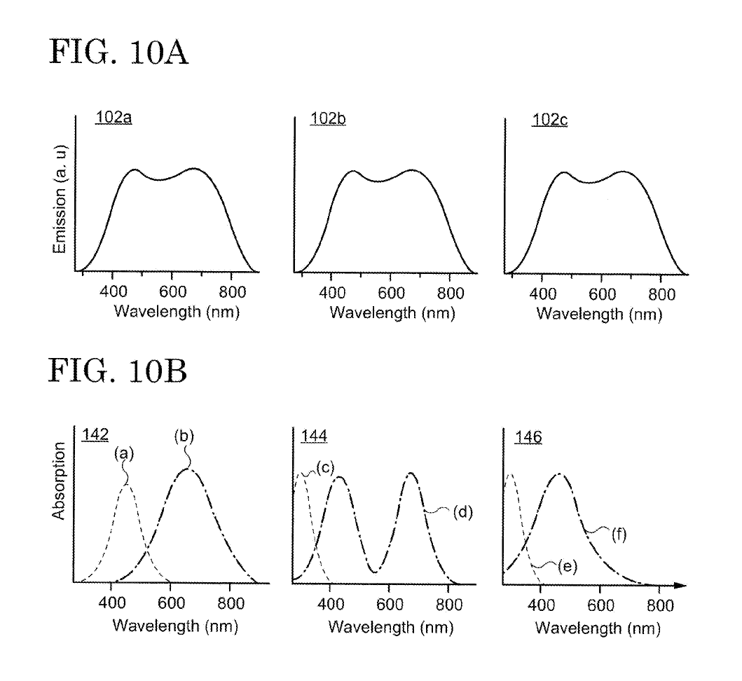

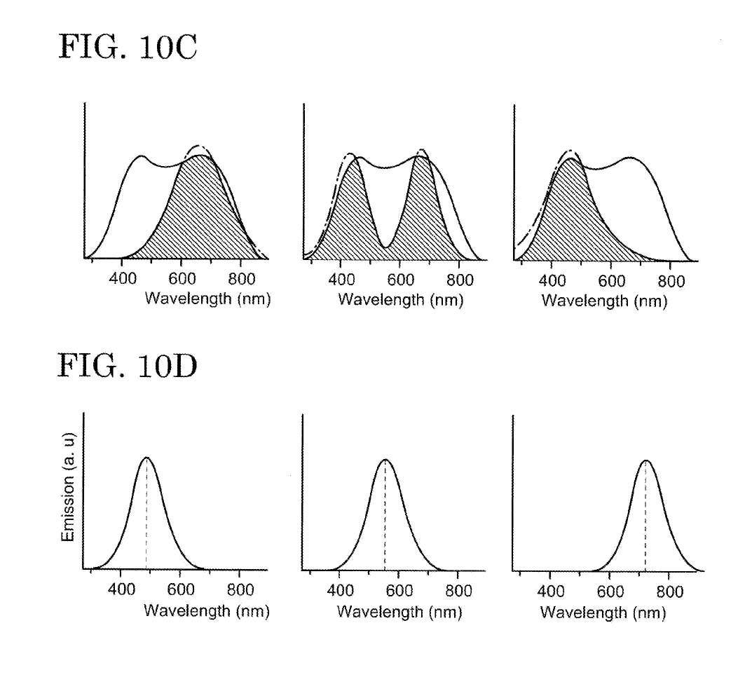

The optical properties of the photochromic layer 140 of the display device 190 are explained by using FIG. 10A to FIG. 10D. Here, explanation is provided for a case where the photochromic layer 140 of the display device 190 has the first photochromic layer 142, the second photochromic layer 144, and the third photochromic layer 146, and blue, green, and red emissions are extracted from the pixels 102a, 102b, and 102c, respectively.

FIG. 10A shows, from left to right, the emission spectra given by the emission layers 126 included in the pixels 102a, 102b, and 102c. As described above, the emission layer 126 has the same structure between the pixels 102a, 102b, and 102c and provides white emission. Hence, these spectra are the same in shape, width, and cover substantially the whole of the visible region.

FIG. 10B shows, from left to right, schematic drawings of the absorption spectra of the first photochromic layer 142, the second photochromic layer 144, and the third photochromic layer 146 before and after photo-isomerization. Explanation of these drawings is omitted because they respectively correspond to FIG. 4B, FIG. 5B, and FIG. 6B.

FIG. 10C shows, from left to right, drawings in which the emission spectrum of the emission layer 126 is overlapped with the absorption spectra of the photochromic materials included in the first photochromic layer 142, the second photochromic layer 144, and the third photochromic layer 146 after photo-isomerization.

When focus is placed on the left figure in FIG. 10C, it can be understood that the emission spectrum overlaps with the absorption (b) in a green to red region, meaning that emission intensity of the pixel 102a is decreased in the green to red region. As a result, blue emission is mainly obtained from the pixel 102a. When focus is placed on the middle figure in FIG. 10C, it can be understood that the emission spectrum overlaps with the absorption (d) in blue and red regions, meaning that emission intensity of the pixel 102b is decreased in the blue and red regions. As a result, green emission is mainly obtained from the pixel 102b. When focus is placed on the right figure in FIG. 10C, it can be understood that the emission spectrum overlaps with the absorption (f) in a blue to green region, meaning that emission intensity of the pixel 102c is decreased in the blue to green region. As a result, red emission is mainly obtained from the pixel 102c.

Therefore, as shown in FIG. 10D, blue, green, and red emissions can be obtained from the pixels 102a, 102b, and 102c, respectively. Hence, although the emission layer 126 provides white emission in all of the pixels 102, different emission colors can be obtained from different pixels even if a color filter is not utilized, by which full-color display can be realized. In other words, the photochromic layer 140 exhibits the same function as a color filter.

As shown in FIG. 9, the photochromic layer 140 may be arranged at a vicinity of the second electrode 112. When full-color display is performed by using white-emissive light-emitting elements in all pixels 102 and a color filter, a color filter is usually arranged at a vicinity of the substrate 170 (e.g., between the filler 160 and the substrate 170). Therefore, a color filter is disposed over the emission region, that is, emission layer 126 through the passivation film 150 and the filler 160. Hence, when a viewing angle is large, a part of the emission from the emission layer 126 is observed through a color filter over the adjacent pixel because a distance between the color filter and the emission layer 126 is large. As a result, the so-called color shift phenomenon occurs, leading to a decrease in display quality.

However, the photochromic layer 140 can be provided so as to be in contact with the second electrode 112 in the display device 190. Therefore, the distance between the emission region and the photochromic layer 140 is small by which generation of the color shift can be effectively suppressed. Accordingly, application of the present embodiment allows production of a display device with high display quality.

### Fourth Embodiment

In the present embodiment, a manufacturing method of the display device 100 according to the present invention is explained. Explanation of the structures the same as those of the First to Third Embodiments may be omitted.

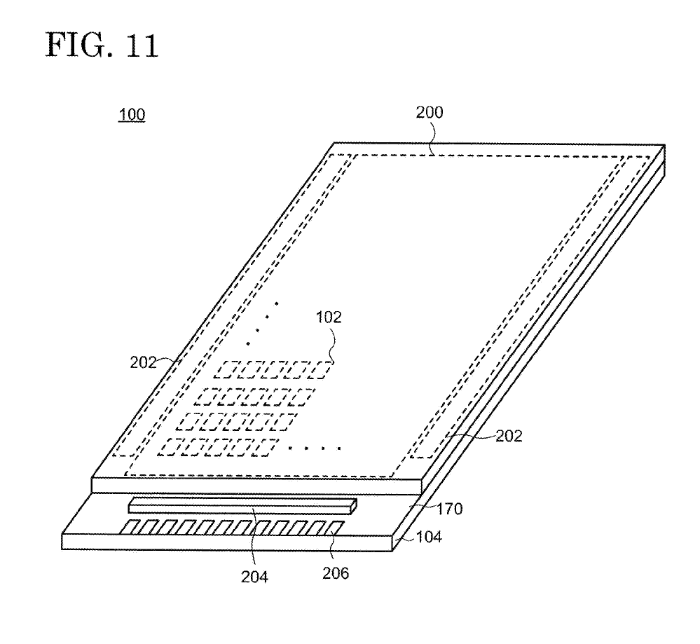

FIG. 11 is a perspective view of the display device 100. The display device 100 possesses, over one surface (top surface) of a substrate 104, a plurality of pixels 102 arranged in a row direction and a column direction, a display region 200 structured by the plurality of pixels 102, scanning-line driver circuits 202, and a data-line driver circuit 204. The substrate 170 covers the display region 200. A variety of signals from an external circuit (not shown) is input to the scanning-line driver circuits 202 and the data-line driver circuit 204 through a connector such as a flexible printed circuit (FPC) connected to terminals 206 formed over the substrate 104, and each pixel 102 is controlled on the basis of these signals.

One or all of the scanning-line driver circuits 202 and the data-line driver circuit 204 may not be necessarily directly formed over the substrate 104. A driver circuit formed over a substrate (e.g., semiconductor substrate) different from the substrate 104 may be mounted on the substrate 104 or the connector, and each pixel 102 may be controlled with the driver circuit. In FIG. 11, an example is shown where the scanning-line driver circuits 202 are covered by the substrate 170, while the data-line driver circuit 204 is prepared over another substrate and then mounted on the substrate 104.

The substrate 104 and the substrate 170 may be a substrate without flexibility, such as a glass substrate, or a substrate having flexibility. A structure may be employed in which a resin film or an optical film such as a circular polarizing plate is bonded instead of the substrate 170. The pixels 102 are arranged in a matrix form. However, the arrangement is not limited, and a stripe arrangement, a delta arrangement, and the like may be applied.

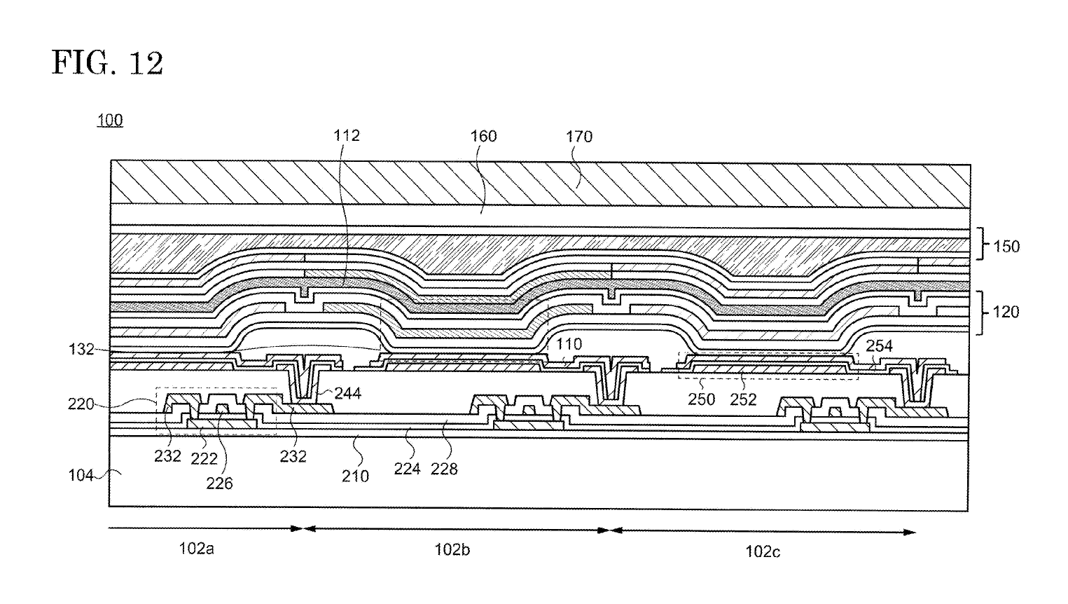

FIG. 12 shows a schematic cross-sectional view of the display device 100 including three continuously arranged pixels 102a, 102b, and 102c.

The pixels 102 including the plurality of pixels 102a, 102b, and 102c each possess, over the substrate 104, elements such as a transistor 220, the light-emitting element 132 electrically connected to the transistor 220, and a supplementary capacitor 250 through a base film 210. FIG. 12 shows an example in which one transistor 220 and one supplementary capacitor 250 are disposed in each pixel 102. However, each pixel 102 may have a plurality of transistors and a plurality of capacitor elements. The structure of the light-emitting element 132 is the same as that described in the First Embodiment. Hereinafter, the manufacturing method of the display device 100 is explained with reference to schematic cross-sectional views thereof.

### 1. Transistor

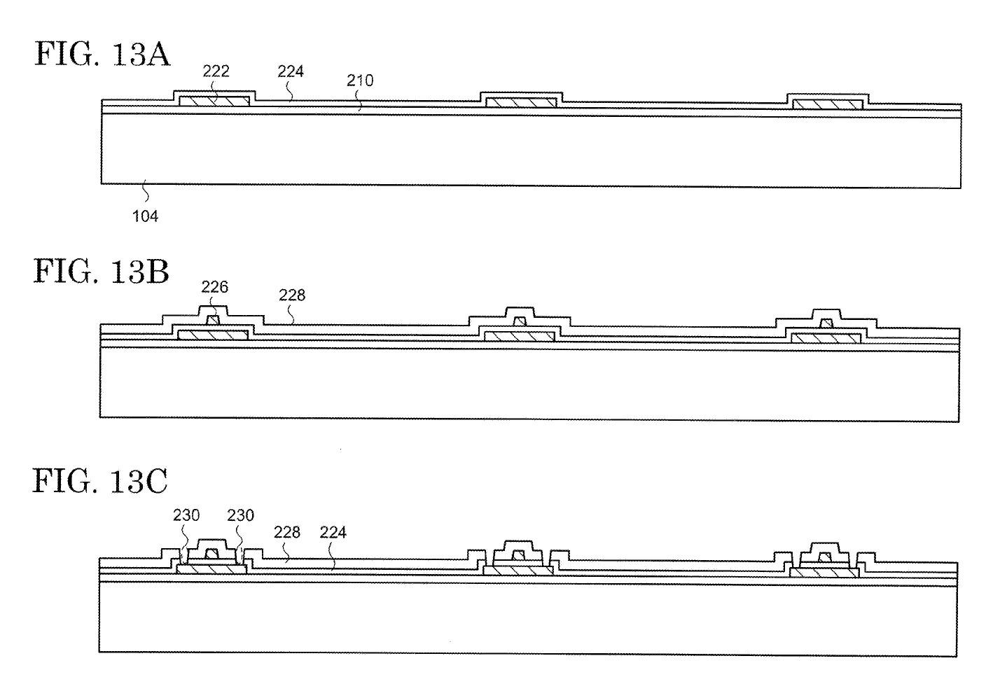

First, as shown in FIG. 13A, the base film 210 is formed over the substrate 104. The substrate 104 has a function to support semiconductor elements included in the display region 200, such as the transistor 220, the light-emitting element 132, and the like. Therefore, a material having heat resistance to a process temperature of a variety of elements formed thereover and chemical stability to chemicals used in the process may be used for the substrate 104. Specifically, the substrate 104 may include glass, quartz, plastics, a metal, ceramics, and the like.

When flexibility is provided to the display device 100, a base material is formed over the substrate 104. In this case, the substrate 104 may be called a supporting substrate. The base material is an insulating film with flexibility and may include a material selected from a polymer material exemplified by a polyimide, a polyamide, a polyester, and a polycarbonate. The base material can be formed by applying a wet-type film-forming method such as a printing method, an ink-jet method, a spin-coating method, and a dip-coating method or a lamination method.

The base film 210 is a film having a function to prevent impurities such as an alkaline metal from diffusing to the transistor 220 and the like from the substrate 104 (and the base material) and may include an inorganic insulator such as silicon nitride, silicon oxide, silicon nitride oxide, and silicon oxynitride. The base film 210 can be formed to have a single-layer or stacked-layer structure by applying a chemical vapor deposition method (CVD method), a sputtering method, or the like. When an impurity concentration in the substrate 104 is low, the base film 210 may not be provided or may be formed to cover a part of the substrate 104.

Next, a semiconductor film 222 is formed (FIG. 13A). The semiconductor film 222 may contain Group 14 elements such as silicon. Alternatively, the semiconductor film 222 may include an oxide semiconductor. As an oxide semiconductor, Group 13 elements such as indium and gallium are represented. For example, a mixed oxide of indium and gallium (IGO) may be used. When an oxide semiconductor is used, the semiconductor film 222 may further contain a Group 12 element, and a mixed oxide of indium, gallium, and zinc (IGZO) is exemplified. Crystallinity of the semiconductor film 222 is not limited, and the semiconductor film 222 may include a crstal state of a single crystalline, polycrystalline, microcrystalline, or amorphous state.

When the semiconductor film 222 includes silicon, the semiconductor film 222 may be prepared with a CVD method by using a silane gas and the like as a raw material. A heat treatment or application of light such as a laser may be performed on amorphous silicon obtained to conduct crystallization. When the semiconductor film 222 includes an oxide semiconductor, the semiconductor film 222 can be formed by utilizing a sputtering method and the like.

Next, a gate insulating film 224 is prepared so as to cover the semiconductor film 222 (FIG. 13A). The gate insulating film 224 may have a single-layer structure or a stacked-layer structure and can be formed with the same method as that of the base film 210.

Next, a gate electrode 226 is formed over the gate insulating film 224 with a sputtering method or a CVD method (FIG. 13B). The gate electrode 226 may be formed with a metal such as titanium, aluminum, copper, molybdenum, tungsten, tantalum or an alloy thereof so as to have a single-layer or stacked-layer structure. For example, a structure in which a highly conductive metal such as aluminum and copper is sandwiched by a metal with a relatively high melting point, such as titanium, tungsten, and molybdenum, can be employed.

Next, an interlayer film 228 is formed over the gate electrode 226 (FIG. 13B). The interlayer film 228 may have a single-layer or stacked layer structure, may include an inorganic insulator such as silicon nitride, silicon oxide, silicon nitride oxide, and silicon oxynitride, and may be prepared with the same method as that of the base film 210. When the interlayer film 228 has a stacked structure, a layer including an inorganic compound may be stacked after forming a layer including an organic compound, for example. After that, doping may be conducted on the semiconductor film 222 to form source/drain regions.

Next, etching is performed on the interlayer film 228 and the gate insulating film 224 to form openings 230 reaching the semiconductor film 222 (FIG. 13C). The openings 230 can be prepared, for example, by conducting plasma etching in a gas including a fluorine-containing hydrocarbon.

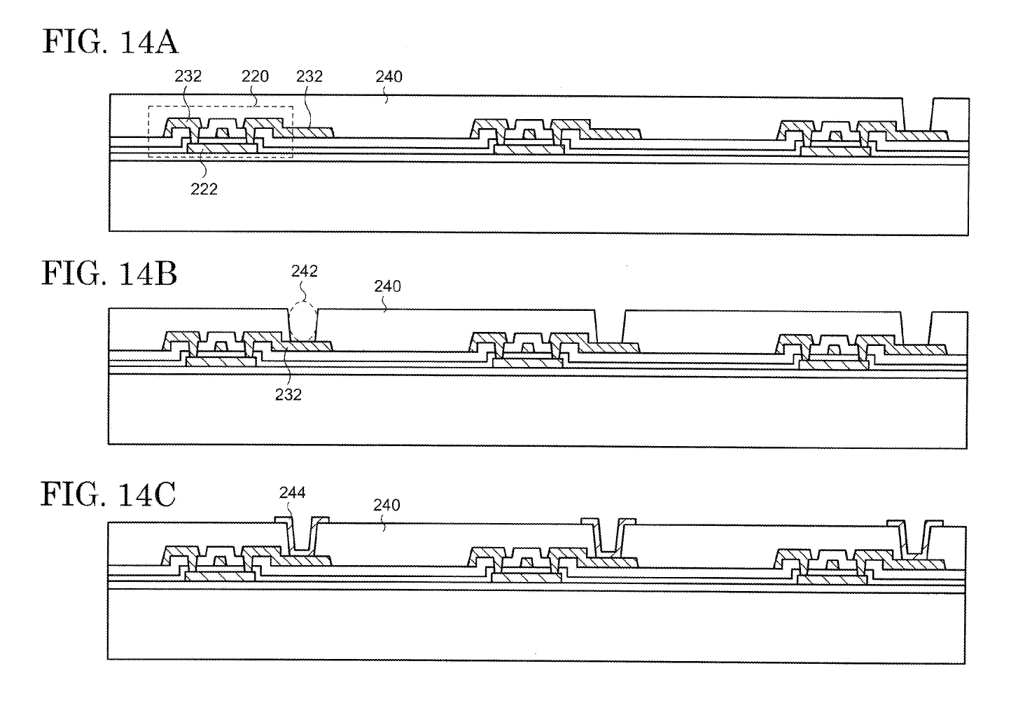

Next, a metal film is formed to cover the openings 230 and processed with etching, forming source/drain electrodes 232 (FIG. 14A). Similar to the gate electrode 226, the metal film may have a single-layer or stacked layer structure and can be formed with a method similar to that of the gate electrode 226. Through the aforementioned processes, the transistor 220 is fabricated. In the present embodiment, the transistor 220 is illustrated as a top-gate type transistor. However, there is no limitation to the structure of the transistor 220, and the transistor 220 may be a bottom-gate type transistor, a multi-gate type transistor having a plurality of gate electrodes 226, or a dual-gate type transistor having a structure in which the semiconductor film 222 is sandwiched by two gate electrodes 226. Moreover, there is no limitation to a vertical relationship between the source/drain electrodes 232 and the semiconductor film 222.

### 2. Supplementary Capacitor and Light-emitting Element

Next, a leveling film 240 is formed so as to cover the transistor 220 (FIG. 14A). The leveling film 240 has a function to absorb depressions, projections, and inclinations caused by the transistor 220 and the like and provide a flat surface. The leveling film 240 can be prepared with an organic insulator. As an organic insulator, a polymer material such as an epoxy resin, an acrylic resin, a polyimide, a polyamide, a polyester, a polycarbonate, and a polysiloxane is represented. The leveling film 240 can be formed with the aforementioned wet-type film-forming method and the like.

Next, etching is performed on the leveling film 240 to form an opening 242 exposing one of the source/drain electrodes 232 (FIG. 14B). After that, a connection electrode 244 is prepared so as to cover this opening 242 and be in contact with the one of the source/drain electrodes 232 of the transistor 220 (FIG. 14C). The connection electrode 244 may be formed by using a conductive oxide transmiting visible light, such as indium-tin oxide (ITO) and indium-zinc oxide (IZO), with a sputtering method or the like. Note that formation of the connection electrode 244 is optional. Deterioration of a surface of the souce/drain electrode 232 can be avoided in the following processes by forming the connection electrode 244, by which generation of contact resistance between the source/drain electrode 232 and the first electrode 110 can be suppressed.

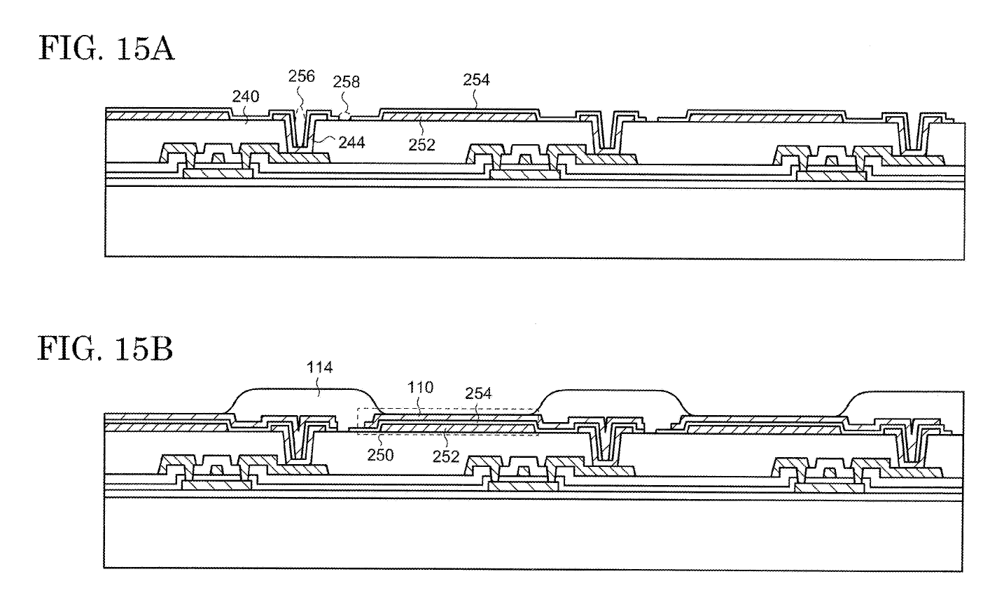

Next, a metal film is formed over the leveling film 240 and processed with etching to form one of electrodes 252 of the supplementary capacitor 250 (FIG. 15A). Similar to the conductive film used for the formation of the source/drain electrodes 232, the metal film used here may have a single layer structure or a stacked layer structure, and a three-layer structure of molybdenum/aluminum/molybdenum may be employed, for example.

Next, an insulating film 254 is formed over the leveling film 240 and the electrode 252 (FIG. 15A). The insulating film 254 not only functions as a protection film for the transistor 220 but also serves as a dielectric in the supplementary capacitor 250. Therefore, it is preferred to use a material with relatively high permitivity. For example, the insulating film 254 can be formed with silicon nitride, silicon nitride oxide, silicon oxynitride, or the like by applying a CVD method or a sputtering method. Openings 256 and 258 are provided in the insulating film 254 (FIG. 15A). The former is provided for electrical connection between the first electrode 110 formed later and the connection electrode 244. The latter is an opening to abstract, through the partition wall 114, water and gas eliminated from the leveling film 240 in a heating process and the like performed after the formation of the partition wall 114.

Next, as shown in FIG. 15B, the first electrode 110 is prepared so as to cover the opening 256. The supplementary capacitor 250 is formed by the first electrode 110, the insulating film 254, and the electrode 252. A potential of the gate electrode 226 of the transistor 220 can be maintained for a longer time by forming the supplementary capacitor 250.

When light emission from the light-emitting element 132 is extracted through the second electrode 112, the first electrode 110 is configured to reflect visible light. In this case, a metal with high reflectance, such as aluminum and silver, or an alloy thereof is used for the first electrode 110. Alternatively, a film of a conductive oxide with a light-transmitting property is formed over a film including the metal or alloy. As a conductive oxide, ITO, IZO, and the like are represented. When a part of the light emission from the light-emitting element 132 is extracted through the first electrode 110, the first electrode 110 may be formed with ITO or IZO.

Next, the partition wall 114 is formed so as to cover an edge portion of the first electrode 110 (FIG. 15B). The formation of the partition wall 114 allows steps caused by the first electrode 110 and the like to be absorbed and first electrodes 110 of the adjacent pixels 102 to be electrically insulated from each other. The partition wall 114 may be prepared with a wet-type film-forming method by using an epoxy resin, an acrylic resin, or the like.

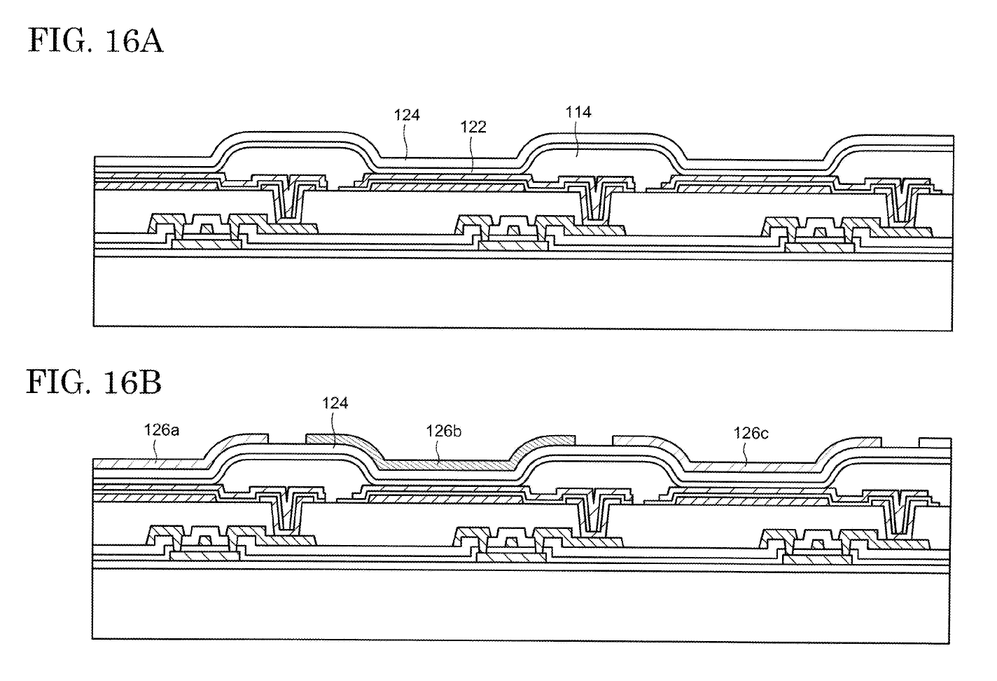

Next, the EL layer 120 and the second electrode 112 of the light-emitting element 132 are formed so as to cover the first electrode 110 and the partition wall 114. Specifically, the hole-injection layer 122 is first formed so as to cover the first electrode 110 and the partition wall 114 (FIG. 16A). A compound to which holes are readily injected, that is, a compound readily oxidized (i.e., electron-donating compound) can be used for the hole-injection layer 122. In other words, a compound whose level of the highest occupied molecular orbiltal (HOMO) is shallow can be used. For example, an aromatic amine such as a benzidine derivative and a triarylamine, a carbazole derivative, a thiophene derivative, a phthalocyanine derivative such as copper phthalocyanine, and the like can be used. Alternatively, a polythiophene derivative or a polyaniline derivative may be used.

Poly(3,4-ethylenedioxydithiophene)/poly(styrenesuflonic acid) is represented as an example. Alternatively, a mixture of an electron-donating compound such as the aforementioned aromatic amine, carbazole derivative, or an aromatic hydrocarbon with an electrone acceptor may be used. As an electron acceptor, a transition-metal oxide such as vanadium oxide and molybdenum oxide, a nitrogen-containing heteroaromatic compound, a heteroaromatic compound having a strong electron-withdrawing group such as a cyano group, and the like are represented.

The hole-transporting layer 124 is further provided over the hole-injection layer 122 (FIG. 16A). The hole-transporting layer 124 has a function to transport holes injected to the hole-injection layer 122 to the emission layer 126, and a material the same as or similar to the material usable in the hole-injection layer 122 can be used. For example, it is possible to use a material having a deeper HOMO level than that of the hole-injection layer 122 or having a difference in HOMO level from the hole-injection layer 122 by approximately 0.5 eV or less.

The hole-injection layer 122 and the hole-transporting layer 124 each may have a single-layer structure or a stacked-layer structure. For example, a thickness of the hole-transporing layer 124 may be changed between the pixels 102 (see FIG. 2). In this case, the hole-transportiong layer 124 in which a pluraltiy of compounds is stacked may be used in the pixel 102 having the hole-transporting layer 124 with a large thickness, while the hole-transporting layer 124 may have a single-layer structure in the pixel 102 having the hole-transporting layer 124 with a small thickness. The hole-injection layer 122 and the hole-transporting layer 124 may be formed with a wet-type film-forming method or a dry-type film-forming method such as an evaporation method.

Next, the emission layer 126 is formed over the hole-transporting layer 124 (FIG. 16B). In the present embodiment, the emission layers 126a, 126b, and 126c which are different in structure or include different materials between the continuous pixels 102a, 102b, and 102c are fabricated. In this case, materials to be included in the respective emission layers 126a, 126b, and 126c are respectively deposited in the pixels 102a, 102b, and 102c by using metal masks. Alternatively, the emission layers 126a, 126b, and 126c may be formed with an ink-jet method.

Each of the emission layers 126a, 126b, and 126c may be formed with a single compound or have a structure of the so-called host-guest type. In the case of the host-guest type, a stillbene derivative, a condensed aromatic compound such as an anthracene derivative, a carbazole derivative, a metal complex including a ligand having a benzoquinolinol as a basic skeleton, an aromatic amine, a nitrogen-containing heteroaromatic compound such as a phenanthroline derivative, and the like can be used as a host material, for example. A fluorescent material such as a coumarin derivative, a pyran derivative, a quinacridone derivative, a tetracene derivative, a pyrene derivative, and an anthracene derivative, or a phosphorescent material such as an irridium-based orthometal complex can be used as a guest. When the emission layers 126a, 126b, and 126c are each prepared with a single layer, the aforementioned host material can be used.

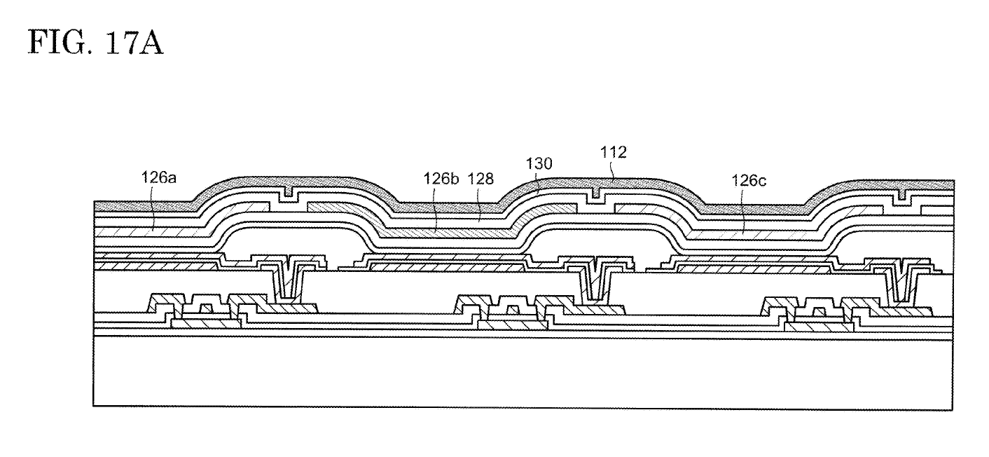

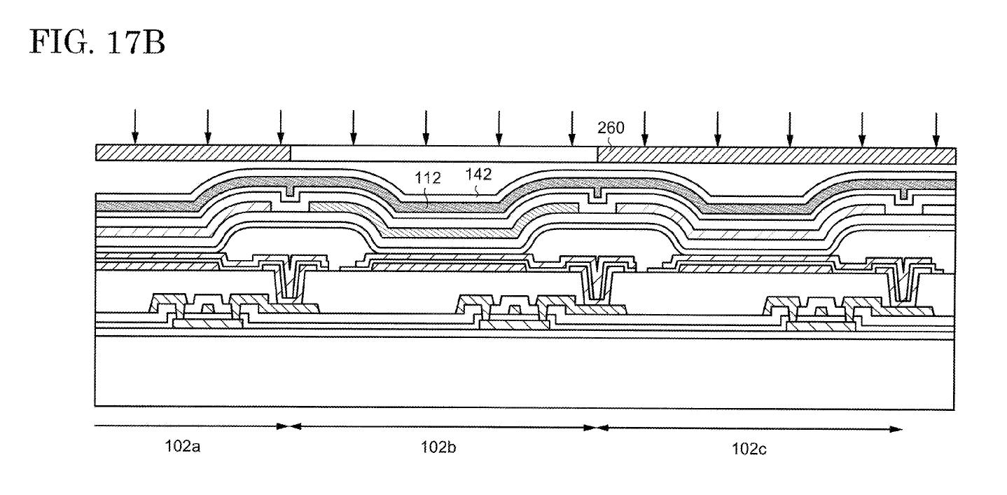

The electron-transporting layer 128 and the electron-injection layer 130 are sequentially formed over the emission layer 126 (FIG. 17A). For the electron-transporting layer 128, a compound readily reduced (i.e., electron-accepting compound) can be used. In other words, a compound whose level of the lowest unoccupied molecular orbiltal (LUMO) is deep can be used. For example, a metal complex including a ligand having a benzoquinolinol as a basic skeleton, such as tris(8-quinolinolato)aluminum and tris(4-methyl-8-quinolinolato)aluminum, a metal complex including a ligand having an oxathiazole or thiazole, and the like are represented. In addition to these metal complexes, an oxadiazole derivative, a thiazole derivative, a triazole derivative, a phenanthroline derivative, and the like can be used.

For the electron-injection layer 130, a compound which promotes electron injection to the electron-transporting layer 128 from the second electrode 112 can be used. For example, a mixture of a compound usable in the electron-transporting layer 128 with an electron-donating material such as lithium or magnesium can be used. Alternatively, an inorganic compound such as lithium fluoride and calcium fluoride may be used. The electron-transporting layer 128 and the electron-injection layer 130 can also be prepared by applying a wet-type film-forming method or a dry-type film-forming method.

After that, the second electrode 112 is formed over the electron-injection layer 130 (FIG. 17A). When a part of light emission from the light-emitting element 132 is extracted through the first electrode 110, a metal such as aluminum and silver or an alloy thereof can be used for the second electrode 112. In contrast, when light emission from the light-emitting element 132 is extracted through the second electrode 112, a conductive oxide with a light-transmitting property, such as ITO, or the like may be used for the second electrode 112. Alternatively, a film containing the aforementioned metal may be formed at a thickness which allows visible light to pass therethrough. In this case, an conductive oxide with a light-transmitting property may be further stacked. With the above processess, the supplementary capacitor 250 and the light-emitting element 132 are prepared.

3. Photochromic layer

Next, the photochromic layer 140 is fabricated over the second electrode 112. Here, an example is explained wherein the photochromic layer 140 has the first photochromic layer 142, the second photochromic layer 144, and the third photochromic layer 146.

First, the first photochromic layer 142 is formed so as to be in contact with the second electrode 112 (FIG. 17B). The first photochromic layer 142 may be formed with a wet-type film-forming method or a dry-type film-forming method. At this time, the first photochromic layer 142 may be continuously formed over the plurality of pixels 102. In other words, the first photochromic layer 142 is not separately formed in each pixel 102 but can be formed to overlap with the plurality of pixels 102.

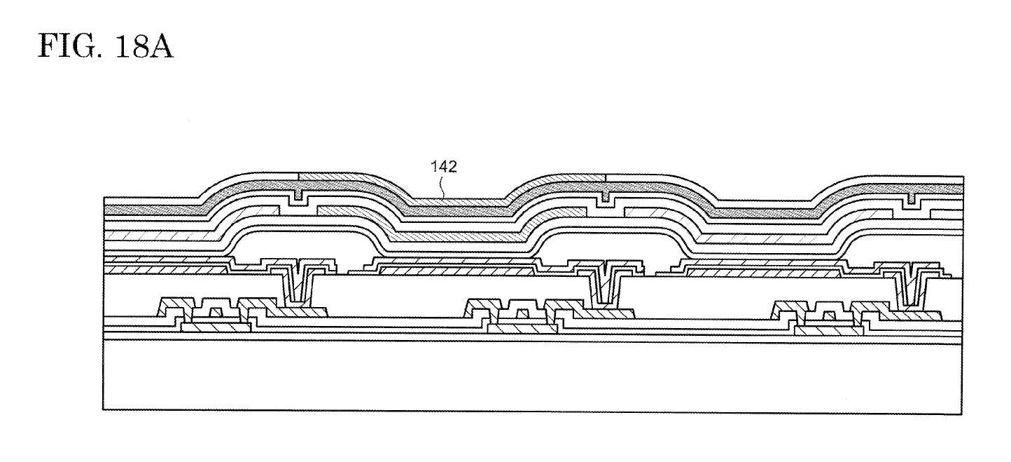

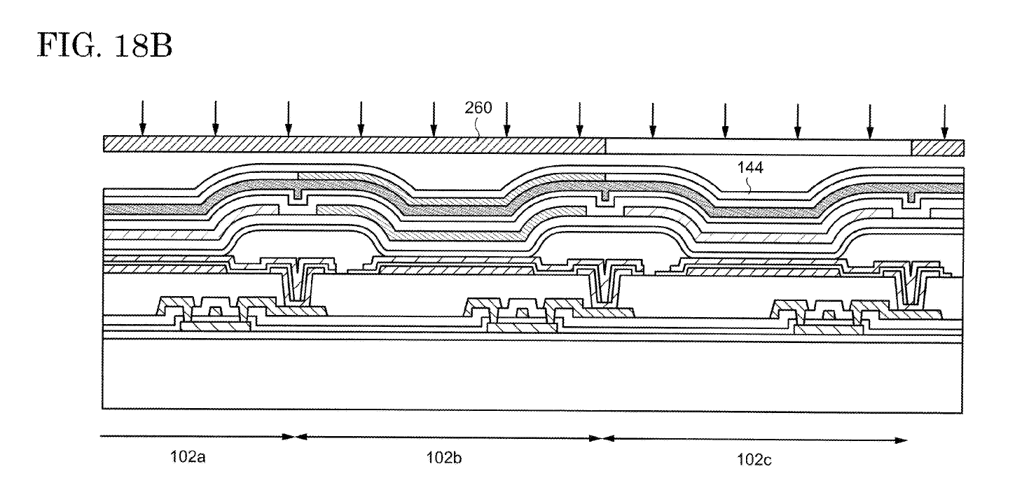

After that, a photomask 260 is arranged over the first photochromic layer 142. The photomask 260 has a light-transmitting portion at a position corresponding to the pixel (pixel 102b in FIG. 17B) in which photo-isomerizaiton is carried out and has a non-light transmitting portion in other regions. After that, photo-isomerizaiton is conducted by applying light with a wavelength corresponding to the absorption wavelength of the photochromic material included in the first photochromic layer 142. With this procedure, the light-irradiated region, that is, the photochromic material in the pixel 102b is capable of having optical properties different from those of the photochromic material in other regions (FIG. 18A).

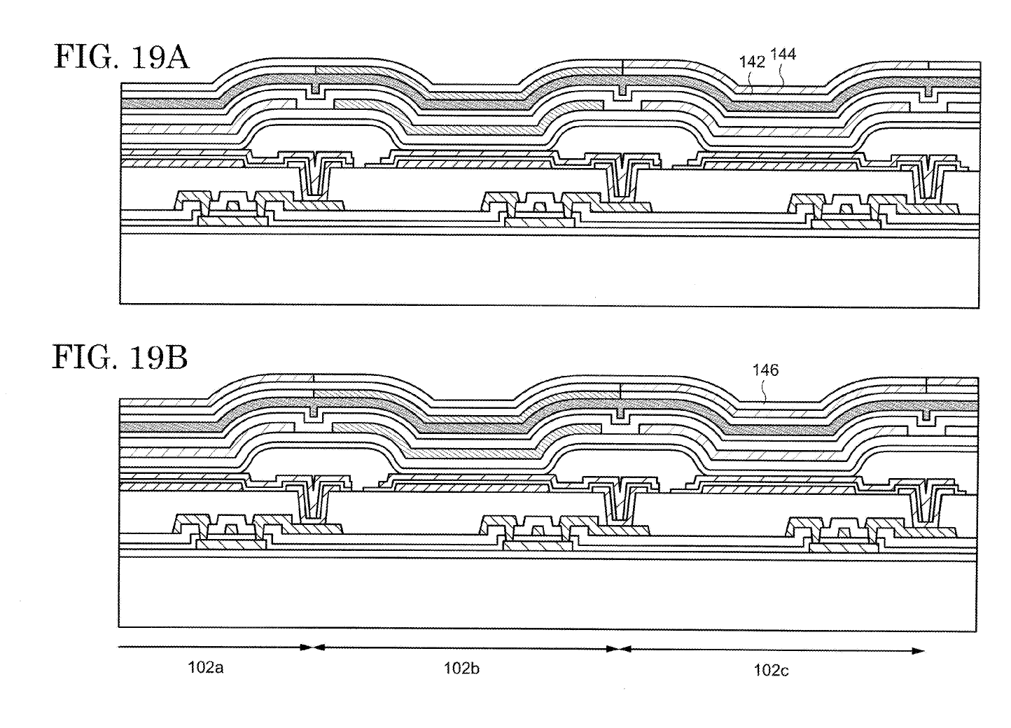

Similarly, as shown in FIG. 18B, the second photochromic layer 144 is prepared over the first photochromic layer 142 with a wet-type film-forming method or a dry-type film-forming method, and then a photomask 260 having a light-transmitting portion at a position corresponding to the pixel (pixel 102c in FIG. 18B) in which photo-isomerizaiton is carried out is arranged. After that, photo-isomerizaiton is conducted by applying light with a wavelength corresponding to the absorption wavelength of the photochromic material included in the second photochromic layer 144. With this procedure, the light-irradiated region, that is, the photochromic material in the pixel 102c is capable of having optical properties different from those of the photochromic material in other regions (FIG. 19A). A similar operation is repeated to form the third photochromic layer 146. In the third photochromic layer 146, the photochromic material in the light-irradiated region (pixel 102a in FIG. 19B) is capable of having optical properties different from those of the photochromic material in other regions.

FIG. 17B to FIG. 19B demonstrate an example in which one photochromic layer is prepared, light-irradiation is carried out, and these processes are repeated. However, a pluraltiy of photochromic layers may be successively formed, and then the exposure processes may be successively performed. For example, the first photochromic layer 142, the second photochromic layer 144, and the first photochromic layer 146 may be formed first, and then these layers may be sequentially exposed.

A thickness of each of the photochromic layers 142, 144, and 146 is not limited and may be equal to or more than 1 μm and equal to or less than 2000 μm, equal to or more than 50 μm and equal to or less than 1000 μm, or equal to or more than 100 μm and equal to or less than 500 μm.

The material used in the photochromic layer 140 is not particularly limited and exemplified by an azobenzene derivative, a spiropyran derivative, a flugide derivative, a stillbene derivative, a diarylethene, an arylarylethene, an arylbenzothienylethene, a viologen derivative, a paracyclophane derivative in which two imidazole skeletons are linked with cyclophane, and the like. Specific structures of these compounds and reaction shemes of their isomerization are shown below. However, a photochromic material applicable in the present embodiment is not limited thereto, and a photochromic material having the optical properties described in the First and Third Embodiments may be used.

In the case of an azobenzene derivative, isomerization proceeds according to the following scheme 1 to exhibit photochromism.

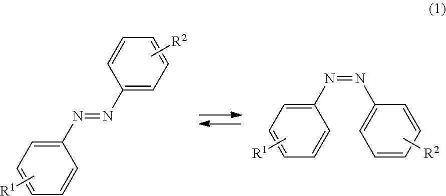

In the case of a spiropyran derivative, isomerization proceeds according to the following scheme 2 to exhibit photochromism.

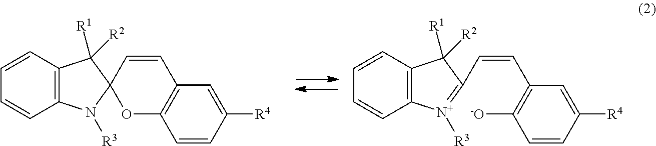

In the case of a flugide derivative, isomerization proceeds according to the following scheme 3 to exhibit photochromism.

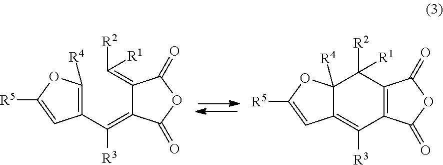

In the case of a diarylethene, isomerization proceeds according to the following scheme 4 to exhibit photochromism.

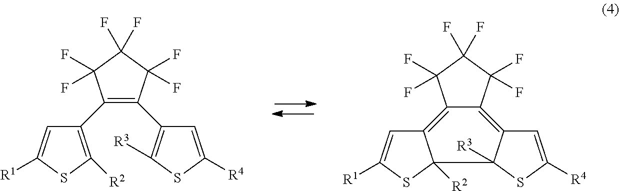

In the case of an arylarylethene, isomerization proceeds according to the following scheme 5 to exhibit photochromism.

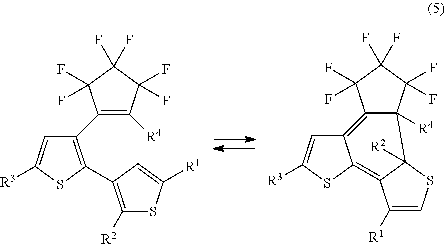

In the case of an arylbenzothienylethene, isomerization proceeds according to the following scheme 6 to exhibit photochromism.

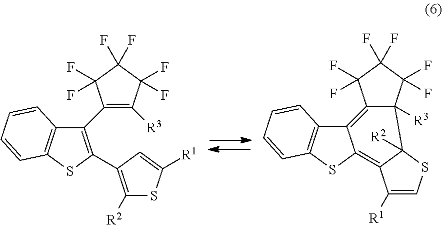

In the case of a paracyclophane, isomerization proceeds according to the following scheme 7 to exhibit photochromism.

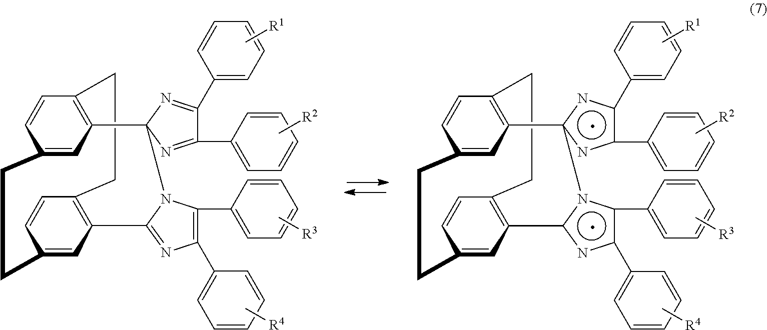

In the aforementioned schemes 1 to 7, R¹, R², R³, R⁴, and R⁵ are each a substituent and independently selected from hydrogen, an alkyl group, an aryl group, a hydroxy group, an alkoxy group, an aryloxy group, an amino group, a substituted amino group, an ester group, halogen, a nitro group, and a cyano group. When a substitution position of the substituent on the benzen ring is not specified in schemes 1 and 7, a plurality of substituents may be introduced to the benzene ring.

As described in the First and Third Embodiments, a compound used in the photochromic layer 140 can be selected as appropriate depending on the method for controlling the light emission from the pixels 102. For example, sincea diarylethene having the following structure shows blue color after isomerization, it can be used in the first photochromic layer 142 which is subjected to photo-isomerization in the pixel 102a giving blue emission.

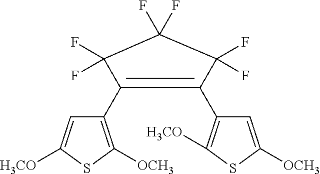 [SMILES: COc1cc(C2=C(c3cc(OC)sc3OC)C(F)(F)C(F)(F)C2(F)F)c(OC)s1]

For example, since a diarylethene having the following structure shows green color after isomerization, it can be used in the second photochromic layer 144 which is subjected to photo-isomerization in the pixel 102b giving green emission.

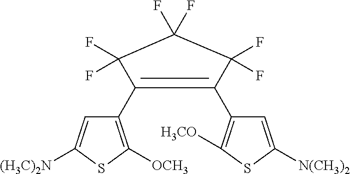

For example, since a diarylethene having the following structure shows red color after isomerization, it can be used in the third photochromic layer 146 which is subjected to photo-isomerization in the pixel 102c giving red emission.

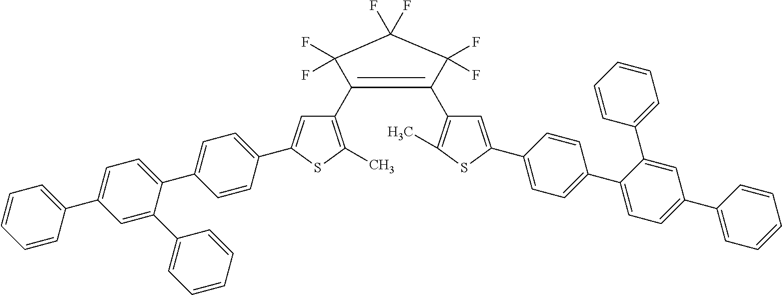 [SMILES: Cc1sc(-c2ccc(-c3ccc(-c4ccccc4)cc3-c3ccccc3)cc2)cc1C1=C(c2cc(-c3ccc(-c4ccc(-c5ccccc5)cc4-c4ccccc4)cc3)sc2C)C(F)(F)C(F)(F)C1(F)F]

### 4. Passivation Film and Other Structures

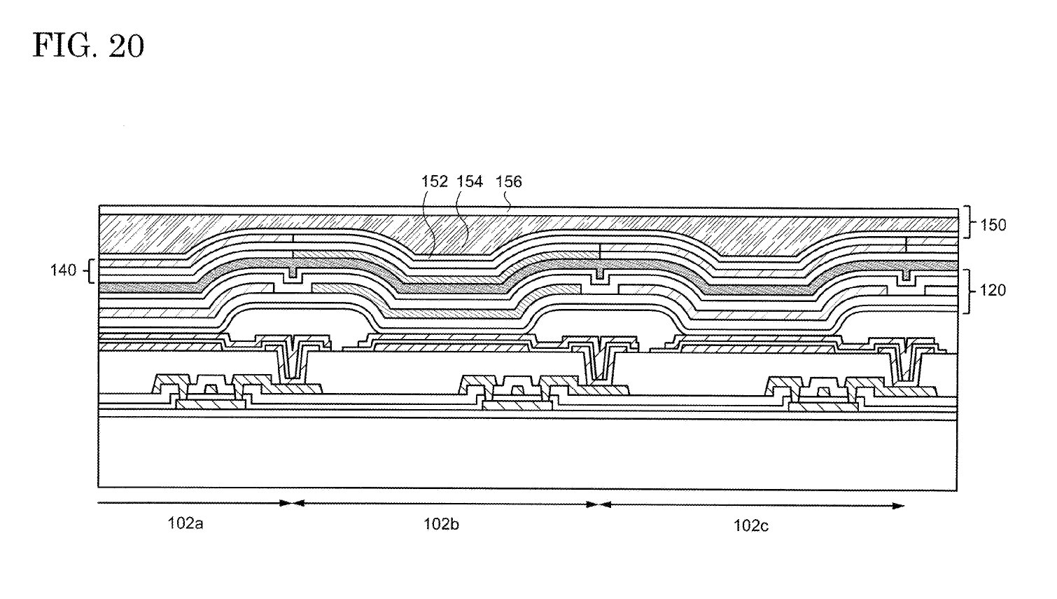

After forming the photochromic layer 140, the passivation film 150 is prepared. Specifically, as shown in FIG. 20, the first layer 152 is first formed over the first photochromic layer 140. The first layer 152 may include an inorganic material such as silicon nitride, silicon oxide, silicon nitride oxide, and silicon oxynitride and may be prepared with a method similar to that of the base film 210.

Next, the second layer 154 is formed. The second layer 154 may contain an organic resin including an acrylic resin, a polysiloxane, a polyimide, a polyester, and the like. Furthermore, as shown in FIG. 20, the second layer 154 may be formed at a thickness so that depressions and projections caused by the partition wall 114 are absorbed and a flat surface is provided. The second layer 154 may be formed by a wet-type film-forming method such as an ink-jet method. Alternatively, the second layer 154 may be prepared by atomizing or vaporizing oligomers serving as a raw material of the aforementioned polymer material at a reduced pressure, spraying the first layer 152 with the oligomers, and then polymerizing the oligomers.

After that, the third layer 156 is formed. The third layer 156 may have the same structure as the first layer 152 and can be formed with the same method as that of the first layer 152.

After that, the substrate 170 is fixed through the filler 160. The filler 160 may contain a polymer material such as a polyester, an epoxy resin, and an acrylic resin and may be formed by applying a printing method, a lamination method or the like. A desiccant may be included in the filler 160. The substrate 170 may include the same material as the substrate 104. When flexibility is provided to the display device 100, a polymer material such as a polyolefin and a polyimide can be applied for the substrate 170 in addition to the aforementioned polymer materials. In this case, the base material is formed over the substrate 104 as described above, and then the elements such as the transistor 220 and the light-emitting elment 132 are fabricated. After that, an interface between the substrate 104 and the base material is irradiated with light such as a laser to reduce adhesion between the substrate 104 and the base material, and then the substrate 104 is physically peeled off, leading to the formation of the flexible display device 100.

An example is described in the present embodiment where the photochromic layer 140 is stacked over the second electrode 112. Howver, the photochromic layer 140 may be formed over the substrate 170 with a wet-type film-forming method or a dry-type film-forming method, and then the substrate 170 may be fixed over the substrate 114 so that the photochromic layer 140 is sandwiched by the substrate 114 and the substrate 170. In this case, the photochromic layer 140 may be formed over the substrate 170 directly or through an insulating film.

Although not shown, a polarizing plate (circular polarizing plate) may be formed without using the substrate 170 as described above. Alternatively, a polarizing plate may be arranged over or under the substrate 170.

As described above, the photochromic layer 140 exhibiting a function the same as a color filter can be continuously formed over the plurality of pixels 102, and control of the optical properties of the photochromic layer 140 in each pixel 102 can be conducted by light-irradiation using a photomask. When a color filter is mounted on a display device, the substrate 170 on which a color filter is fabricated is usually fixed over the substrate 104 through the display region 200. Therefore, an increase in resolution and a decrease in size of the pixel 102 make it difficult to align the color filter with the pixel, which readily causes a reduction in yield. On the other hand, light-irradiation can be carried out with high positional accuracy by using a photomask. Therefore, the photochromic material can be certainly isomerized at the positions corresponding to the pixels 102. Accordingly, accurate control of the optical properties of the photochromic layer 140 can be readily performed in every pixel 102 even in the case of a high-resolution display, which allows production of display device capable of reproducing a high-quality image at low cost.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

In the specification, although the cases of the organic EL display device are exemplified, the embodiments can be applied to any kind of display devices of the flat panel type such as other self-emission type display devices, liquid crystal display devices, and electronic paper type display device having electrophoretic elements and the like. In addition, it is apparent that the size of the display device is not limited, and the embodiment can be applied to display devices having any size from medium to large.

It is properly understood that another effect different from that provided by the modes of the aforementioned embodiments is achieved by the present invention if the effect is obvious from the description in the specification or readily conceived by persons ordinarily skilled in the art.

What is claimed is:

1. A display device comprising:
a substrate;
a first light-emitting element over the substrate; and
a second light-emitting element over the substrate, the second light-emitting element being adjacent to the first light-emitting element,
wherein each of the first light-emitting element and the second light-emitting element comprises:
a first electrode;
an EL layer over the first electrode;
a second electrode over the EL layer; and
a photochromic layer over the second electrode, the photochromic layer including a photochromic material, and
the photochromic material of the photochromic layer included in the first light-emitting element is different in chemical structure from the photochromic material of the photochromic layer included in the second light-emitting element.

2. The display device according to claim 1,
wherein the photochromic material of the photochromic layer included in the first light-emitting element and the photochromic material of the photochromic layer included in the second light-emitting element are the same in composition.

3. The display device according to claim 1,
wherein the photochromic layer included in the first light-emitting element is different in light-absorption property from the photochromic layer included in the second light-emitting element.

4. The display device according to claim 1,
wherein the photochromic layer is continuously arranged over the first light-emitting element and the second light-emitting element.

5. The display device according to claim 1,
wherein the photochromic layer included in the first light-emitting element absorbs a part of light emitted from the second light-emitting element.

6. The display device according to claim 1, further comprising a passivation film over the photochromic layer.

7. The display device according to claim 1, further comprising a passivation film between the second electrode and the photochromic layer so as to cover the EL layer,
wherein the passivation film includes an inorganic film.

8. A display device comprising:
a substrate;
a first light-emitting element over the substrate; and
a second light-emitting element over the substrate, the second light-emitting element being adjacent to the first light-emitting element,
wherein each of the first light-emitting element and the second light-emitting element comprises:
a first electrode;
an EL layer over the first electrode;
a second electrode over the EL layer;
a first photochromic layer over the second electrode, the first photochromic layer including a first photochromic material; and
a second photochromic layer over the first photochromic layer, the second photochromic layer including a second photochromic material,
the first photochromic material included in the first light-emitting element is different in chemical structure from the first photochromic material included in the second light-emitting element, and
the second photochromic material included in the first light-emitting element is different in chemical structure from the second photochromic material included in the second light-emitting element.

9. The display device according to claim 8,
wherein the first photochromic material included in the first light-emitting element and the first photochromic material included in the second light-emitting element are the same in composition, and
the second photochromic material included in the first light-emitting element and the second photochromic material included in the second light-emitting element are the same in composition.

10. The display device according to claim 8,
wherein the first photochromic material included in the first light-emitting element is different in light-absorption property from the first photochromic material included in the second light-emitting element, and
the second photochromic material included in the first light-emitting element is different in light-absorption property from the second photochromic material included in the second light-emitting element.

11. The display device according to claim 8,
wherein the first photochromic layer and the second photochromic layer are continuously arranged over the first light-emitting element and the second light-emitting element.

12. The display device according to claim 8,
wherein the first photochromic layer included in the first light-emitting element absorbs a part of light emitted from the second light-emitting element, and
the second photochromic layer included in the second light-emitting element absorbs a part of light emitted from the first light-emitting element.

13. The display device according to claim 8, further comprising a passivation film over the second photochromic layer.

14. The display device according to claim 8, further comprising a passivation film between the second electrode and the first photochromic layer so as to cover the EL layer,
wherein the passivation film includes an inorganic film.

15. A method for manufacturing a display device, the method comprising:
forming a first electrode in each of a first pixel and a second pixel adjacent to the first pixel;
forming an EL layer over the first electrode of the first pixel and the first electrode of the second pixel;
forming a second electrode over the EL layer;
forming a photochromic layer over the second electrode, the photochromic layer being continuously arranged over the first pixel and the second pixel and including a photochromic material; and
performing light irradiation on at least one of the first pixel and the second pixel to isomerize the photochromic material.

16. The method according to claim 15,
wherein the photochromic material is configured so that an absorption property changes after the isomerization.

17. The method according to claim 15,
wherein the photochromic material is configured to absorb a part of light emitted from the second pixel after the isomerization.

18. The method according to claim 15, further comprising forming a passivation film over the photochromic layer.
